(19) United States
(12) Patent Application Publication
(10) Pub. No.: US 2026/0213490 A1
(43) Pub. Date: Jul. 23, 2026

(54) OPTICAL APPARATUS AND METHOD FOR MANUFACTURING OPTICAL APPARATUS

(71) Applicant: Sony Semiconductor Solutions Corporation, Kanagawa (JP)

(72) Inventor: Shogo ONO, Kanagawa (JP)

(21) Appl. No.: 19/134,309

(22) PCT Filed: Oct. 11, 2023
(86) PCT No.: PCT/JP2023/036818

§ 371 Date: May 30, 2025

(30) Foreign Application Priority Data
Dec. 7, 2022 (JP) 2022-195290

(51) Int. Cl. H01S 5/02335; H01S 5/02; H01S 5/02345; H01S 5/028; H01S 5/042; H01S 5/183; H01S 5/42

(52) U.S. Cl. CPC H01S 5/02335; H01S 5/0203; H01S 5/02345; H01S 5/028; H01S 5/04252; H01S 5/04256; H01S 5/18305; H01S 5/18388; H01S 5/423

(57) ABSTRACT

In an embodiment, a light emitting device comprises a substrate including a plurality of light emitting sections and a film disposed on the substrate. The substrate includes a groove surface at an end of a surface of the substrate.

### CROSS REFERENCE TO RELATED APPLICATIONS

This application claims the benefit of Japanese Priority Patent Application JP 2022-195290 filed Dec. 7, 2022, the entire contents of which are incorporated herein by reference.

### TECHNICAL FIELD

The technology according to the present disclosure (hereinafter referred to as “present technology”) relates to an optical apparatus and a method for manufacturing an optical apparatus.

### BACKGROUND ART

In the related art, an optical apparatus is known that includes an element including a substrate and an element constitution section provided on the substrate (see, for example, PTL 1). The known optical apparatus is obtained by dividing and individuating multiple element constitution sections provided together on a wafer.

### CITATION LIST

### Patent Literature

PTL 1: JP 2021-22665A

### SUMMARY

### Technical Problem

However, in the optical apparatus in the past, the substrate includes a top portion both at ends of one surface side and ends of the other surface side opposite to the one surface side, and thus, a manufacturing process may lead to problems such as peel-off of a thin film deposited on the substrate and chipping of the substrate.

Thus, it is desirable to provide an optical apparatus that can suppress problems such as peel-off of a thin film deposited on the substrate and chipping of the substrate in a manufacturing process.

### Solution to Problem

In order to address the above described problem, a light emitting device comprises a substrate including a plurality of light emitting sections and a film disposed on the substrate. The substrate includes a groove surface at an end of a surface of the substrate.

In an example embodiment, the film is a thin film.

In an example embodiment, the film is an anti-reflection film.

In an example embodiment, the film is disposed on the groove surface.

In an example embodiment, the film is an electrode.

In an example embodiment, the film includes wiring.

In an example embodiment, the film is an Au thin film.

In an example embodiment, the film comprises an anode electrode and an insulating film.

In an example embodiment, each light emitting section is a vertical cavity surface emitting laser (VCSEL).

In an example embodiment, the light emitting device is a back side emitting type.

In an example embodiment, the plurality of light emitting sections are arranged in two dimensionally in a staggered arrangement.

In an example embodiment, the substrate includes a plurality of optical elements, each corresponding to a respective light emitting section.

In an example embodiment, the optical elements are convex lenses.

In an example embodiment, the groove surface is a first surface of a groove in the substrate, the groove having the first surface and a second surface which are symmetrically shaped.

In an example embodiment, the groove is a V-shaped groove, which upon separation, provides the groove surface as a chamfered portion at the end of the surface of the substrate.

In an example embodiment, the second surface of the groove is removed from the light emitting device after separation of the substrate.

In an example embodiment, the groove surface is a curved surface.

In an example embodiment, with respect to a thickness direction of the substrate, the groove surface has an inclination angle of 60° or less.

In an example embodiment, a method of manufacturing light emitting devices, comprises:
forming a plurality of light emitting sections on a first surface of a substrate;
forming a plurality of grooves on a second surface of the substrate;
forming a film on the second surface;
sticking a tape to the second surface;
releasing a plurality of light emitting devices from the tape.

In an example embodiment, the light emitting devices are optical chips.

In an example embodiment, each of the optical chips include a plurality of back side emitting vertical cavity surface emitting lasers.

In an example embodiment, further comprises forming optical elements on the second surface.

In an example embodiment, the grooves are formed by etching.

In an example embodiment, the tape includes at least one of a dicing tape or a protection tape.

### BRIEF DESCRIPTION OF DRAWINGS

FIG. 1 is a cross-sectional view of an optical apparatus according to Example 1 according to a first embodiment of the present technology.

FIG. 2 is a plan view of an optical apparatus according to Example 1 according to the first embodiment of the present technology.

FIG. 3 is a partially enlarged cross-sectional view of the optical apparatus according to Example 1 according to the first embodiment of the present technology.

FIG. 4 is a partially enlarged view of FIG. 1.

FIG. 5 is a flowchart for describing an example of a method for manufacturing the optical apparatus in FIG. 1.

FIG. 6A and FIG. 6B are respectively a cross-sectional view and a plan view illustrating a process of manufacturing the optical apparatus in FIG. 1.

FIG. 7A and FIG. 7B are respectively a cross-sectional view and a plan view illustrating the process of manufacturing the optical apparatus in FIG. 1.

FIG. 8A and FIG. 8B are respectively a cross-sectional view and a plan view illustrating the process of manufacturing the optical apparatus in FIG. 1.

FIG. 9A and FIG. 9B are respectively a cross-sectional view and a plan view illustrating the process of manufacturing the optical apparatus in FIG. 1. FIG. 9C is a cross-sectional view illustrating the process of manufacturing the optical apparatus in FIG. 1.

FIG. 10A is a cross-sectional view illustrating the process of manufacturing the optical apparatus in FIG. 1. FIG. 10B is a partially enlarged view of FIG. 10A.

FIG. 11 is a plan view illustrating the process of manufacturing the optical apparatus in FIG. 1.

FIG. 12A and FIG. 12B are respectively a cross-sectional view and a plan view illustrating the process of manufacturing the optical apparatus in FIG. 1.

FIG. 13A and FIG. 13B are respectively cross-sectional views illustrating the process of manufacturing the optical apparatus in FIG. 1.

FIG. 14A and FIG. 14B are respectively cross-sectional views illustrating the process of manufacturing the optical apparatus in FIG. 1.

FIG. 15A is a cross-sectional view illustrating the process of manufacturing the optical apparatus in FIG. 1. FIG. 15B is a partially enlarged view of FIG. 15A.

FIG. 16 process of manufacturing the optical apparatus in FIG. 1.

FIG. 17 is a cross-sectional view of an optical apparatus according to Example 2 according to the first embodiment of the present technology.

FIG. 18 is a cross-sectional view of an optical apparatus according to Example 3 according to the first embodiment of the present technology.

FIG. 19A is a cross-sectional view of an optical apparatus according to Example 4 according to the first embodiment of the present technology. FIG. 19B is a cross-sectional view of an optical apparatus according to Example 5 according to the first embodiment of the present technology.

FIG. 20A is a cross-sectional view of an optical apparatus according to Example 6 according to the first embodiment of the present technology. FIG. 20B is a cross-sectional view of an optical apparatus according to Example 7 according to the first embodiment of the present technology.

FIG. 21 is a partially enlarged cross-sectional view of an optical apparatus according to Example 8 according to the first embodiment of the present technology.

FIG. 22 is a partially enlarged cross-sectional view of an optical apparatus according to Example 9 according to the first embodiment of the present technology.

FIG. 23 is a partially enlarged cross-sectional view of an optical apparatus according to Example 10 according to the first embodiment of the present technology.

FIG. 24A is a cross-sectional view of an optical apparatus according to Example 11 according to the first embodiment of the present technology. FIG. 24B is a partially enlarged view of FIG. 24A.

FIG. 25A is a cross-sectional view of an optical apparatus according to Example 1 according to a second embodiment of the present technology. FIG. 25B is a cross-sectional view of an optical apparatus according to Example 2 of the second embodiment of the present technology.

FIG. 26A is a cross-sectional view of an optical apparatus according to Example 3 according to the second embodiment of the present technology. FIG. 26B is a cross-sectional view of an optical apparatus according to Example 4 according to the second embodiment of the present technology.

FIG. 27 is a cross-sectional view depicting a modification (1) of a chamfered portion.

FIG. 28 is a cross-sectional view depicting a modification (2) of the chamfered portion.

FIG. 29A is a cross-sectional view of an optical apparatus according to Modification 1 according to the first embodiment of the present technology. FIG. 29B is a cross-sectional view of an optical apparatus according to Modification 2 according to the first embodiment of the present technology.

FIG. 30A is a cross-sectional view of an optical apparatus according to Modification 3 according to the first embodiment of the present technology. FIG. 30B is a cross-sectional view of an optical apparatus according to Modification 4 according to the first embodiment of the present technology.

FIG. 31A is a cross-sectional view of an optical apparatus according to Modification 5 according to the first embodiment of the present technology. FIG. 31B is a cross-sectional view of an optical apparatus according to Modification 6 according to the first embodiment of the present technology.

FIG. 32A is a cross-sectional view of an optical apparatus according to Modification 7 according to the first embodiment of the present technology. FIG. 32B is a cross-sectional view of an optical apparatus according to Modification 8 according to the first embodiment of the present technology. FIG. 32C is a cross-sectional view of an optical apparatus according to Modification 9 according to the first embodiment of the present technology.

FIG. 33A is a cross-sectional view of an optical apparatus according to Modification 10 according to the first embodiment of the present technology. FIG. 33B is a cross-sectional view of an optical apparatus according to Modification 11 according to the first embodiment of the present technology.

FIG. 34 is a cross-sectional view of an optical apparatus according to Modification 12 according to the first embodiment of the present technology.

FIGS. 35A to 35C are respectively cross-sectional views illustrating a process of manufacturing an optical apparatus according to Comparative Example 1.

FIGS. 36A to 36C are respectively cross-sectional views illustrating the process of manufacturing the optical apparatus according to Comparative Example 1.

FIGS. 37A to 37C are respectively cross-sectional views illustrating the process of manufacturing the optical apparatus according to Comparative Example 1.

FIGS. 38A and 38B are respectively cross-sectional views illustrating the process of manufacturing the optical apparatus according to Comparative Example 1.

FIG. 39A is a cross-sectional view illustrating the process of manufacturing the optical apparatus according to Comparative Example 1. FIG. 39B is a partially enlarged view of FIG. 39A.

FIGS. 40A and 40B are respectively cross-sectional views illustrating the process of manufacturing the optical apparatus according to Comparative Example 1.

FIGS. 41A to 41C are respectively cross-sectional views illustrating a process of manufacturing an optical apparatus according to Comparative Example 2.

FIGS. 42A and 42B are respectively cross-sectional views illustrating the process of manufacturing the optical apparatus according to Comparative Example 2.

FIGS. 43A and 43B are respectively cross-sectional views illustrating the process of manufacturing the optical apparatus according to Comparative Example 2.

FIG. 44A is a cross-sectional view illustrating the process of manufacturing the optical apparatus according to Comparative Example 2. FIG. 44B is a partially enlarged view of FIG. 44A.

FIGS. 45A and 45B are respectively cross-sectional views illustrating the process of manufacturing the optical apparatus according to Comparative Example 2.

FIGS. 46A and 46B are respectively cross-sectional views illustrating the process of manufacturing the optical apparatus according to Comparative Example 2.

FIG. 47 is a plan view depicting a configuration example of a surface emitting laser to which the present technology may be applied.

FIG. 48A is a cross-sectional view of FIG. 47 taken across line X-X. FIG. 48B is a cross-sectional view of FIG. 47 taken across line Y-Y.

FIG. 49 is a diagram depicting an example of application of the optical apparatus according to an embodiment of the present technology to a distance measuring apparatus.

FIG. 50 is a block diagram depicting an example of a general configuration of a vehicle control system.

FIG. 51 is an explanatory diagram depicting an example of an installation position of the distance measuring apparatus.

### DESCRIPTION OF EMBODIMENTS

With reference to the attached drawings, suitable embodiments of the present technology will be described in detail. Note that, in the present specification and drawings, duplicate descriptions are omitted by assigning the same reference signs to components with substantially the same functions and configurations. Embodiments described below illustrate typical embodiments of the present technology and do not make the scope of the present technology narrowly interpreted. Even in a case where an optical apparatus and a method for manufacturing an optical apparatus according to the present technology are described as producing multiple advantageous effects, the optical apparatus and the method for manufacturing an optical apparatus according to the present technology are only required to produce at least one advantageous effect. The advantageous effects described herein are illustrative and not restrictive, and may produce other advantageous effects.

Additionally, the description will be in the following order.
0. Introduction
1. Optical Apparatus according to Example 1 according to First Embodiment of Present Technology
2. Optical Apparatus according to Example 2 according to First Embodiment of Present Technology
3. Optical Apparatus according to Example 3 according to First Embodiment of Present Technology
4. Optical Apparatus according to Example 4 according to First Embodiment of Present Technology
5. Optical Apparatus according to Example 5 according to First Embodiment of Present Technology
6. Optical Apparatus according to Example 6 according to First Embodiment of Present Technology
7. Optical Apparatus according to Example 7 according to First Embodiment of Present Technology
8. Optical Apparatus according to Example 8 according to First Embodiment of Present Technology
9. Optical Apparatus according to Example 9 according to First Embodiment of Present Technology
10. Optical Apparatus according to Example 10 according to First Embodiment of Present Technology
11. Optical Apparatus according to Example 11 according to First Embodiment of Present Technology
12. Optical Apparatus according to Example 1 according to Second Embodiment of Present Technology
13. Optical Apparatus according to Example 2 according to Second Embodiment of Present Technology
14. Optical Apparatus according to Example 3 according to Second Embodiment of Present Technology
15. Optical Apparatus according to Example 4 according to Second Embodiment of Present Technology
16. Modifications of Present Technology
17. Example of Application to Electronic Equipment
18. Example of Application of Optical Apparatus to Distant Measurement Apparatus
19. Example of Mounting of Distant Measurement Apparatus in Mobile Body

### 0. Introduction

In the related art, an optical apparatus is known that includes a light emitting element and a light receiving element and that includes an element constitution section on a substrate (see, for example, PTL 1). The optical apparatus in the past is obtained by performing dicing to individuate multiple element constitution sections provided together on a wafer, into separate element constitution sections. Before the dicing step, thin films, for example, a protection film, an anti-reflection film, and the like are often formed on the wafer. In an optical apparatus in the past, substrates into which the wafer is diced include a top portion on the thin film side. For example, in the dicing step and the substrate thinning step, a fixation tape is stuck to a surface of the substrate on a thin film side. The tape cuts into the thin film at the top portion of the substrate, and thus when the tape is released, a problem may occur, such as peel-off of the thin film together with the tape or chipping or the substrate.

Accordingly, as a result of earnest studies, the inventors have developed an optical apparatus according to the present technology as an optical apparatus that can suppress problems such as peel-off of thin films (for example, a protection film, an anti-reflection film, and the like) deposited on the substrate and chipping of the substrate.

The optical apparatus according to the present technology is an optical apparatus including a light emitting function and/or a light receiving function and expected to be utilized for sensing, imaging, and communication, and in various technical fields.

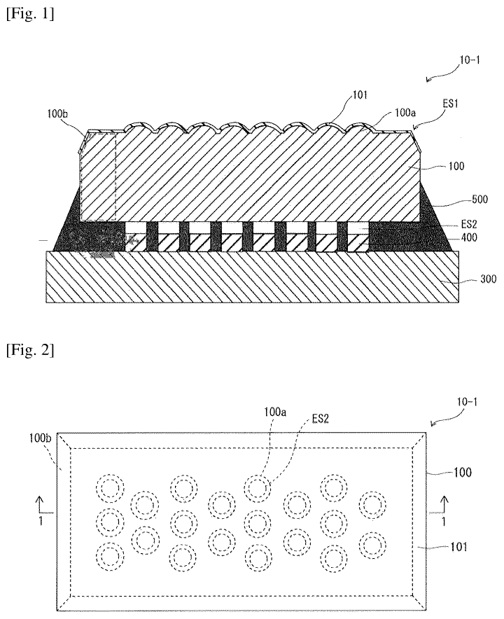

First and a second embodiments of the optical apparatus according to the present technology will be described in detail by taking several examples. In the description below, for convenience, the upper side of cross-sectional views such as FIG. 1 is assumed to be an up side, whereas the lower side is assumed to be a down side.

### 1. Optical Apparatus According to Example 1 According to First Embodiment of Present Technology

The optical apparatus according to Example 1 according to the first embodiment of the present technology will be described below with reference to the drawings.

### Configuration of Optical Apparatus According to First Embodiment

### (General Configuration)

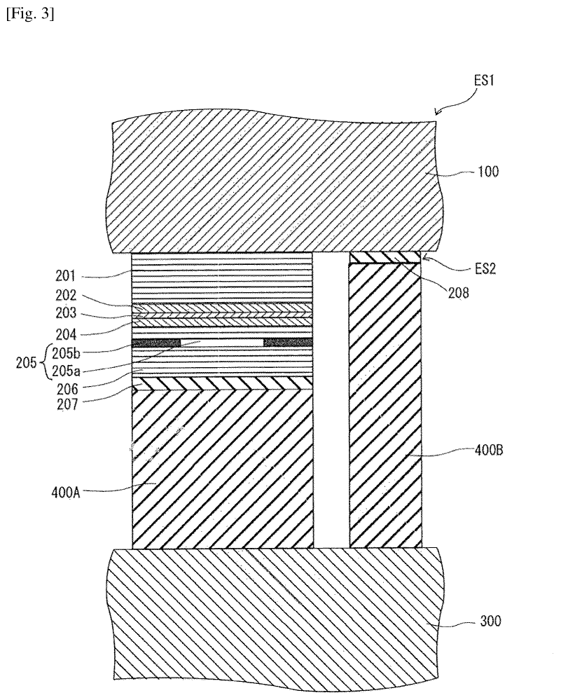

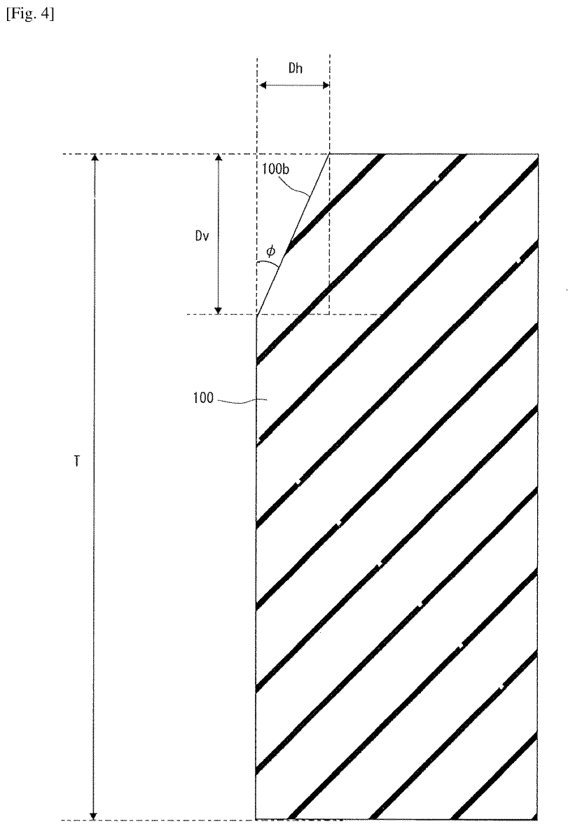

FIG. 1 is a cross-sectional view (taken along line 1-1 in FIG. 2) of an optical apparatus 10-1 according to Example 1 according to the first embodiment of the present technology. FIG. 2 is a plan view of the optical apparatus 10-1 according to Example 1 according to the first embodiment of the present technology. FIG. 3 is a partially enlarged cross-sectional view (obtained by partially enlarging the cross section in FIG. 2) of the optical apparatus according to Example 1 according to the first embodiment of the present technology. FIG. 4 is a partially enlarged view (enlarged view of an area in FIG. 1 enclosed by an alternate long and short dash line) of FIG. 1.

As depicted in FIG. 1 as an example, the optical apparatus 10-1 includes an element including a first element constitution section ES1 including a substrate 100 and multiple second element constitution sections ES2 provided on one surface (lower surface) of the substrate 100. As an example, the element is a surface emitting laser array including multiple light emitting sections. As an example, each light emitting section is a vertical cavity surface emitting laser (VCSEL) including the first and second element constitution sections ES1 and ES2. Here, multiple light emitting sections shares the first element constitution section ES1, and the light emitting sections include different second element constitution sections ES2. As an example, the first element constitution section ES1 includes the substrate 100. The VCSEL as each light emitting section has an oscillation wavelength A set to, for example, from 780 to 950 nm. As an example, the VCSEL as each light emitting section is a back surface emitting VCSEL that emits light toward the other surface (upper surface) side of the substrate 100.

As an example, the multiple second element constitution sections ES2 is two-dimensionally arranged (for example, in a staggered arrangement) as depicted in FIG. 2. Note that the multiple second element constitution sections ES2 may be in, for example, a matrix arrangement, a one-dimensional arrangement, or the like.

As an example, the second element constitution sections ES2 includes a light emitting layer 203. The second element constitution sections ES2 further includes first and a second reflectors 201 and 206 located above and below the light emitting layer 203 to sandwich the light emitting layer 203 in an up-down direction, a first clad layer 202 disposed between the light emitting layer 203 and the first reflector 201, a second clad layer 204 disposed between the light emitting layer 203 and the second reflector 206, and an oxidized constriction layer 205 disposed in the second reflector 206. The second element constitution sections ES2 further includes an anode electrode 207 provided on a surface (lower surface) of the second reflector 206 opposite to the light emitting layer 203 side, and a cathode electrode 208 (n-side electrode) provided on one surface (lower surface) of the substrate 100.

That is, in the second element constitution sections ES2, the following layers are laminated on one surface of the substrate 100 in the order: the first reflector 201, the first clad layer 202, the light emitting layer 203, the second clad layer 204, the second reflector 206 containing the oxidized constriction layer 205, and the anode electrode 207 (p-side electrode).

As an example, the second element constitution section ES2 includes a mesa M including the light emitting layer 203, the first and second reflectors 201 and 206, the first and second clad layers 202 and 204, the oxidized constriction layer 205, and the second reflector 206. The anode electrode 207 is provided at a top portion (lower end) of the mesa M, and the cathode electrode 208 is provided on the one surface (lower surface) of the substrate 100 in an area around the mesa M.

In each light emitting section, the first and second reflectors 201 and 206 and the light emitting layer 203 constitute a resonator. As an example, the resonator has a resonator length that is an integral multiple of the half-wave length (λ/2) of a standing wave generated in the resonator.

As an example, the optical apparatus 10-1 further includes another substrate 300 joined to each second element constitution section ES2 via a bump 400 (first and a second bumps 400A and 400B depicted in FIG. 3 are collectively referred to as the bump 400). That is, the surface emitting laser array as an element of the optical apparatus 10-1 is connected to the other substrate 300 in a junction-down (flip chip) fashion. A laser driver is provided on the other substrate 300.

As an example, the periphery of the junction between the second element constitution section ES2 and the other substrate 300 is filled with an underfill 500 (liquid curable resin used for sealing) including an insulating material (for example, resin) (see FIG. 1). This is effective in reinforcing the junction and suppressing corrosion of the elements and the laser driver.

### (Substrate)

As an example, the substrate 100 is a semiconductor substrate. Specifically, as an example, the substrate 100 is an n-type semiconductor substrate and includes, for example, n-GaAs.

### (First Reflector)

As an example, the first reflector 201 is a semiconductor multilayer film reflector (semiconductor DBR). Specifically, as an example, the first reflector 201 is an n-type semiconductor DBR and includes, for example, two different types of n-AlGaAs layers of Al compositions (high refractive-index layers and low refractive-index layers) alternately laminated to an optical thickness of λ/4.

(First Clad layer)

The first clad layer 202 is an n-type semiconductor layer and includes, for example, n-AlGaGs. The clad layer is also referred to as a “spacer layer.”

(Light Emitting Layer) As an example, the light emitting layer 203 includes a quantum well structure including a barrier layer and a quantum well layer including a GaAs-based compound semiconductor (for example, InGaAs/AlGaAs). The quantum well structure may be a single quantum well structure (QW structure) or a multiple quantum well structure (MQW structure). As an example, the light emitting layer 203 includes a light emitting area (current injection area) corresponding to a non-oxidized area 205a (current passage area) of the oxidized constriction layer 205 described below. Note that the light emitting layer 203 may include multiple QW structures or multiple MQW structures laminated via tunnel junctions. As an example, the light emitting layer 203 is disposed at the anti-node position of a standing wave generated in the resonator. The light emitting layer 203 is also referred to as an “active layer.”

### (Second Clad Layer)

The second clad layer 204 is a p-type semiconductor layer and includes, for example, a p-AlGaAs. The clad layer is also referred to as a “spacer layer.”

### (Second Reflector)

As an example, the second reflector 206 is a semiconductor multilayer film reflector (semiconductor DBR). Specifically, as an example, the second reflector 206 is a p-type semiconductor DBR, and includes, for example, two different types of p-AlGaAs layers of Al compositions (high refractive-index layers and low refractive-index layers) alternately laminated to an optical thickness of λ/4. A slightly higher reflectance is set for the second reflector 206 than for the first reflector 201.

### (Oxidized Constriction Layer)

As an example, the oxidized constriction layer 205 is disposed inside the second reflector 206 at the node position of the standing wave. The oxidized constriction layer 205 includes a non-oxidized area 205a and an oxidized area 205b surrounding the non-oxidized area 205a. The non-oxidized area 205a includes a semiconductor (for example, p-GaAs) and functions as a current passage area. The oxidized area 205b includes an insulator (for example, Al, O,), and functions as a current and light constriction area.

### (Anode Electrode)

The anode electrode 207 includes at least one type of metal (including alloy) selected from the group including, for example, Au, Ag, Pd, Pt, Ni, Ti, V, W, Cr, Al, Cu, Zn, Sn, and In. In a case where the anode electrode 207 has a laminate structure, the anode electrode 207 includes materials, for example, Ti/Au, Ti/Al, Ti/Al/Au, Ti/Pt/Au, Ni/Au, Ni/Au/Pt, Ni/Pt, Pd/Pt, or Ag/Pd. Note that a contact layer (for example, a p-GaAs layer highly doped with p-type impurities) may be provided between the anode electrode 207 and the second reflector 206.

### (Cathode Electrode)

The cathode electrode 208 includes at least one type of metal (including alloy) selected from the group including, for example, Au, Ag, Pd, Pt, Ni, Ti, V, W, Cr, Al, Cu, Zn, Sn, and In. In a case where the cathode electrode 208 has a laminate structure, the cathode electrode 208 includes materials, for example, Ti/Au, Ti/Al, Ti/Al/Au, Ti/Pt/Au, Ni/Au, Ni/Au/Pt, Ni/Pt, Pd/Pt, or Ag/Pd. Note that a contact layer (for example, an n-GaAs layer highly doped with n-type impurities) may be provided between the substrate 100 and the cathode electrode 208.

### (Another Substrate)

As an example, the other substrate 300 is a semiconductor substrate. Specifically, as an example, the other substrate 300 is a silicon substrate. The other substrate 300 is provided with the laser driver as described above. As an example, the laser driver includes a power supply, and a p-type MOSFET (Metal-Oxide-Semiconductor Field-effect Transistor) as a switching element. Here, the laser driver includes multiple switching elements individually corresponding to the multiple second element constitution sections ES2. Each of the multiple switching elements includes a drain connected to a terminal (terminal of the laser driver) joined via a first bump 400A to the anode electrode 207 of the corresponding second element constitution section ES2, and a source connected to a positive electrode of the power supply. A terminal of the laser driver connected to a negative electrode of the power supply and the cathode electrode 208 are connected via a second bump 400B. A gate voltage can be applied to a gate of each switching element. In addition to the power supply and the multiple switching elements, the laser driver includes circuit elements, for example, a capacitor, a resistor, and the like. Note that an n-type MOSFET may be used as each switching element and that the drain may be connected to the negative electrode of the power supply and that the source may be connected to the terminal (terminal of the laser driver) joined via a second bump 400B to the cathode electrode 208 of the corresponding second element constitution section ES2. The laser driver can independently control the multiple switching elements and independently drive the multiple light emitting sections.

### (Bump)

Each of the first and second bumps 400A and 400B included in the bump 400 is a conductive bump including at least one type of metal selected from, for example, Au, Ag, Cu, Sn, and Pb.

### (Details of Substrate)

As an example, the substrate 100 as the first element constitution section ES1 is rectangular as seen in plan view as depicted in FIG. 2, and includes four sides (ends in four directions) on each of one surface (lower surface) and the other surface (upper surface) that are opposite to each other. As an example, the substrate 100 includes a chamfered portion 100b at least at one end (for example, all ends) of the other surface side (upper surface side) opposite to the one surface side (lower surface side). The substrate 100 is covered by a thin film 101 from the other surface (upper surface) side. Specifically, the other surface (upper surface) and the chamfered portion 100b (or groove surface) of the substrate 100 are covered by the thin film 101. As shown in FIG. 1, each groove surface or chamfered portion 100b may be a surface of a groove between two areas of the substrate as explained further below. The terms chamfered portion and groove area may be used interchangeably in this disclosure. Here, the thin film 101 is an anti-reflection film (AR film).

As an example, as depicted in FIG. 4, the chamfered portion 100b is an inclined surface formed by cutting off corners of other surface side (upper surface side) of the substrate, which is rectangular in longitudinal section, the inclined surface being inclined at an angle Φ with respect to the thickness direction (up-down direction) of the substrate 100.

As depicted in FIG. 1, the substrate 100 as the first element constitution section ES1 includes an optical element 100a provided on the other surface (upper surface) of the substrate 100. At least the optical element 100a and the chamfered portion 100b are covered by the thin film 101. As an example, the optical element 100a has a convex lens structure formed on the other surface of the substrate 100. The convex lens structure as the optical element 100a is provided on the other surface (upper surface) of the substrate 100 at multiple positions corresponding to the multiple second element constitution sections ES2 (see FIG. 2). That is, the multiple optical elements 100a is two-dimensionally arranged (for example, in a staggered manner) on the other surface (upper surface) of the substrate 100. Each optical element 100a includes a light focusing function.

The inclination angle @ (see FIG. 4) of the chamfered portion 100b with respect to the thickness direction of the substrate 100 is preferably 60° or less and more preferably 50° or less and much more preferably 40° or less and furthermore preferably 30° or less.

For the chamfered portion 100b, the ratio of a length Dv related to the thickness direction of the substrate 100 to a length Dh related to the in-plane direction of the substrate 100 is preferably 2 or more and more preferably 3 or more and much more preferably 4 or more and furthermore preferably 5 or more.

The length Dv of the chamfered portion 100b in the thickness direction of the substrate 100 is preferably one-third or less and more preferably one-fourth or less and much more preferably one-fifth or less and furthermore preferably one-sixth or less of the thickness T of the substrate 100. Additionally, Dv is preferably one-twentieth or more and more preferably one-fifteenth or more and much more preferably one-tenth or more of the thickness T of the substrate 100. Specifically, for example, when the substrate 100 has a thickness T of 100 μm, Dv is preferably 5 μm or more and 33 μm or less.

### Operation of Optical Apparatus According to Example 1

Operation of the optical apparatus 10-1 will be described with respect to FIG. 3. In the optical apparatus 10-1, when at least one switching element of the laser driver is turned on, in the corresponding light emitting section, a current flows from the anode electrode 207 side into the second element constitution section ES2. The current flowing via the anode electrode 207 and a part of the second reflector 206 is constricted by the oxidized constriction layer 205 and injected into the light emitting layer 203 via the other part of the second reflector 206 and the second clad layer 204. At this time, the light emitting layer 203 emits light, and the light reciprocates between the first reflector 201 and the second reflector 206 while being amplified by the light emitting layer 203 and constricted by the oxidized constriction layer 205. When oscillation conditions are satisfied, laser light (focused beam) is emitted from the optical element 100a provided on the other surface (upper surface) of the substrate 100. The current flowing through the light emitting layer 203 flows out from the cathode electrode 208 into the laser driver via the first clad layer 202, the first reflector 201, and the substrate 100.

### Method for Manufacturing Optical Apparatus According to Example 1

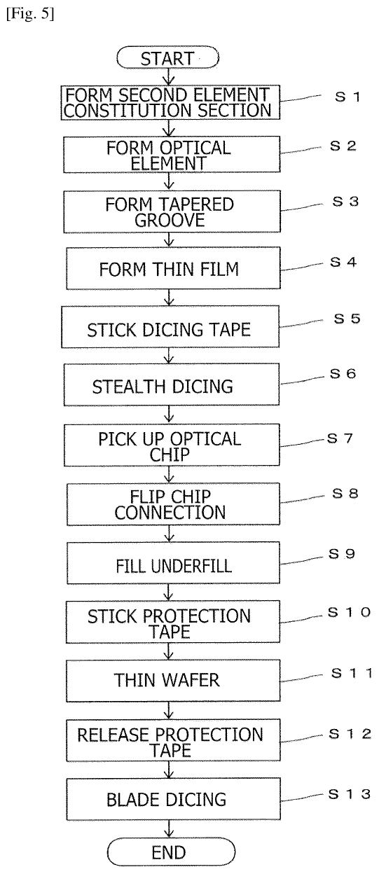

Now, a method for manufacturing the optical apparatus 10-1 will be described with reference to a flowchart in FIG. 5 and the like. Here, an integrated series of multiple optical apparatuses 10-1 is generated at one time and is then divided into the individual optical apparatuses 10-1.

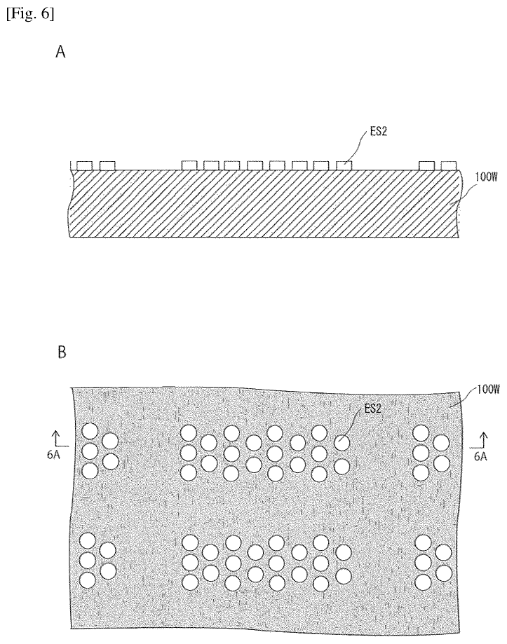

In the first step S1, the second element constitution sections ES2 are formed (see FIG. 6A (cross-sectional view taken along line 6A-6A in FIG. 6B) and FIG. 6B (plan view)). Specifically, the multiple second element constitution sections ES2 for each optical apparatuses 10-1 is formed on a wafer 100W that is a material of the substrate 100. Specifically, first, in a deposition chamber, a metal organic chemical vapor deposition (MOCVD) or a molecular beam epitaxy (MBE) is used to deposit the first reflector 201, the first clad layer 202, the light emitting layer 203, the second clad layer 204, and the second reflector 206 containing an oxidized layer that is a material of the oxidized constriction layer 205, on one surface (upper surface) of the wafer 100W in this order. Then, photolithography and etching are used to form a mesa constituting a part of the second element constitution section ES2 on the substrate 100. Then, the mesa is exposed to a high-temperature steam atmosphere to oxidize the oxidized layer from side surfaces to form an oxidized constriction layer 205. Finally, for example, liftoff is used to form an anode electrode 207 on the top portion of the mesa and to form a cathode electrode 208 on an area of the substrate 100 around the mesa.

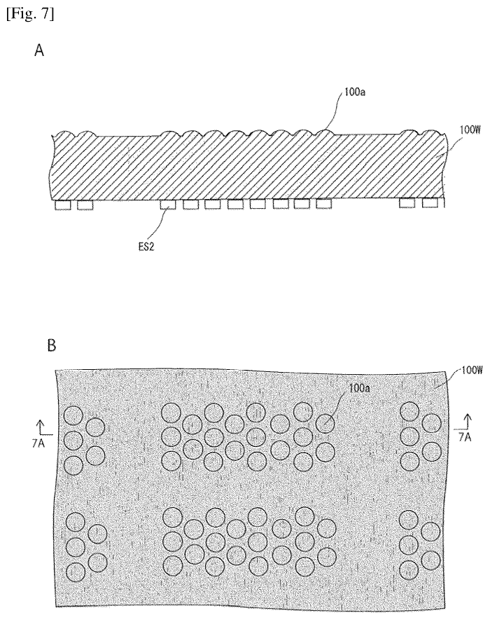

In the next step S2, the optical element 100a is formed (see FIG. 7A (cross-sectional view taken along line 7A-7A in FIG. 7B) and FIG. 7B (plan view)). Specifically, the wafer 100W is inverted, and then photolithography and etching are used to form a convex lens structure on the other surface (upper surface) of the wafer 100W as the optical element 100a.

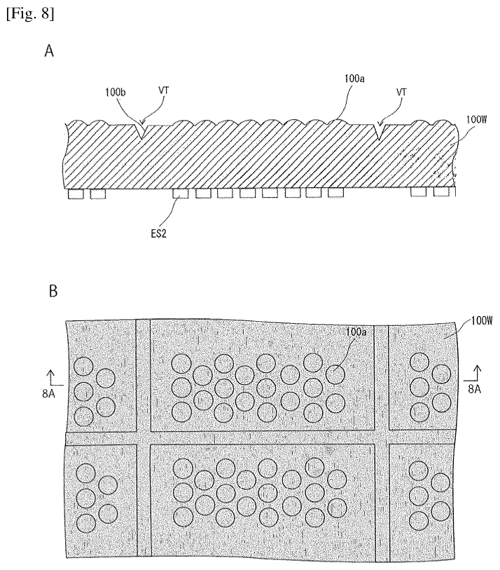

In the next step S3, a tapered groove VT (groove with a tapered (for example, V-shaped) cross section) is formed (see FIG. 8A (cross-sectional view taken along line 8A-8A in FIG. 8B) and FIG. 8B (plan view)). Specifically, ablation laser processing is performed on the other surface (upper surface) of the wafer 100W provided with the optical element 100a at a scribe position (planned cutting position) to form a tapered groove VT including the chamfered portion 100b as an inner wall surface (inclined surface). Note that the tapered groove VT may be formed, by photolithography and etching, simultaneously with formation of the optical element 100a or while formation of the optical element 100a is not being performed. Note that the “tapered groove” as used herein means a groove that is progressively narrower toward the bottom portion.

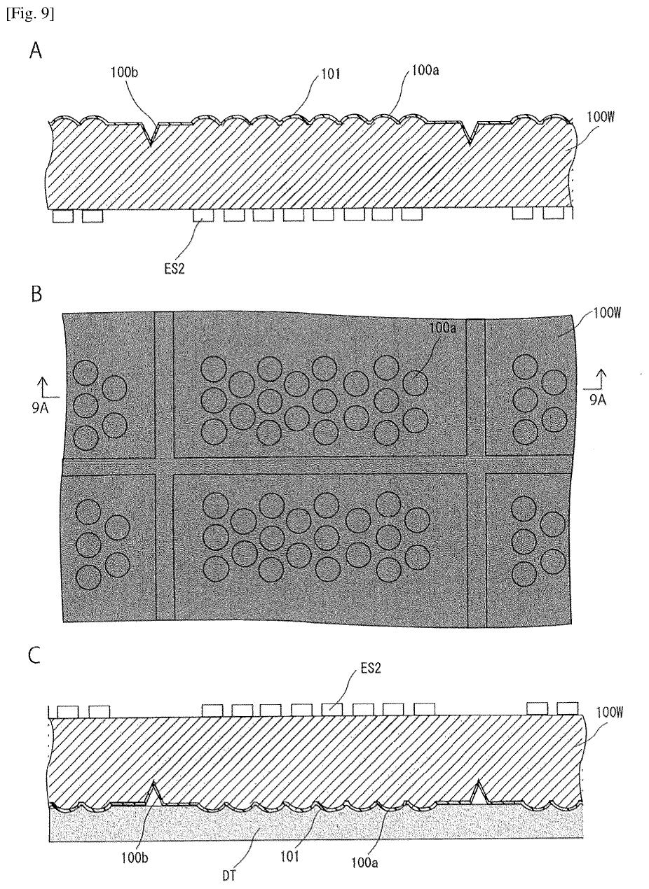

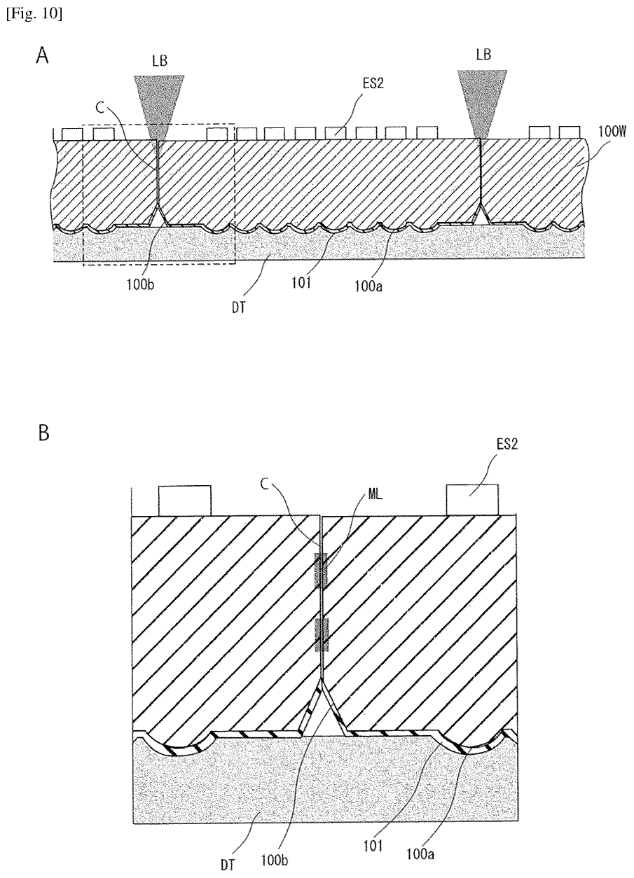

In the next step S4, the thin film 101 is formed (see FIG. 9A (cross-sectional view taken along line 9A-9A in FIG. 9B) and FIG. 9B (plan view)). Specifically, for example, vacuum deposition, sputtering, or the like is used to deposit the thin film 101 all over the upper surface (upper surface) of the wafer 100W provided with the tapered groove VT.

In the next step S5, a dicing tape DT is stuck (see FIG. 9C (cross-sectional view)).

Specifically, the wafer 100W is inverted, and the dicing tape DT (adhesive tape used to fix the wafer 100W during dicing) is stuck to the surface (lower surface) of the wafer 100W on the thin film 101 side.

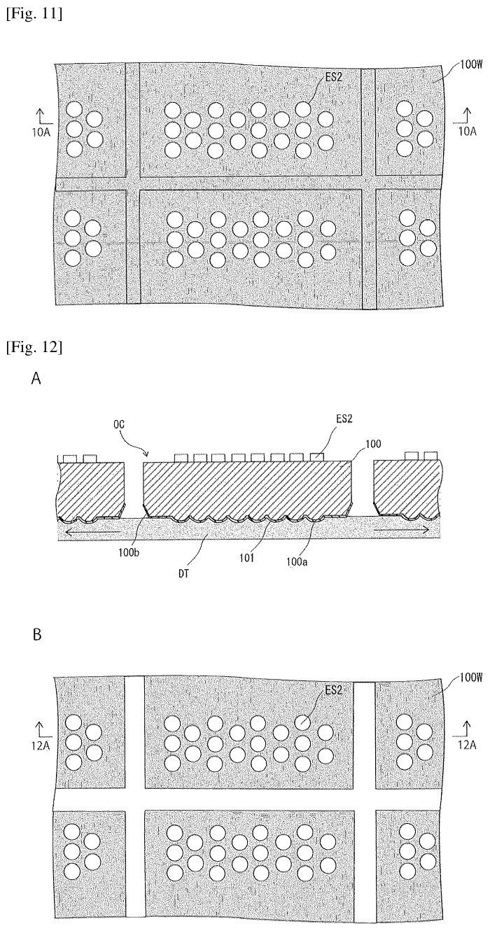

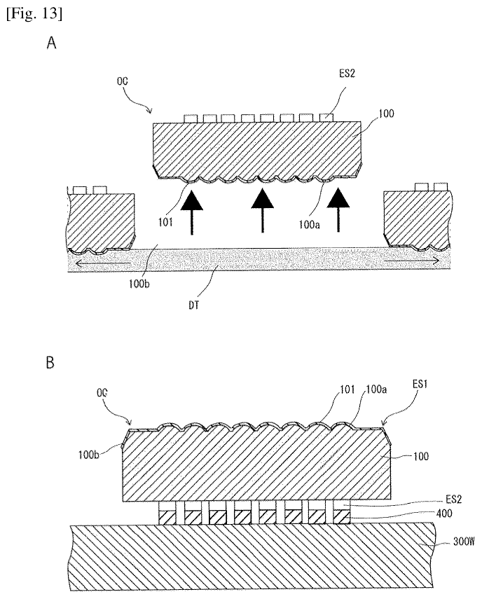

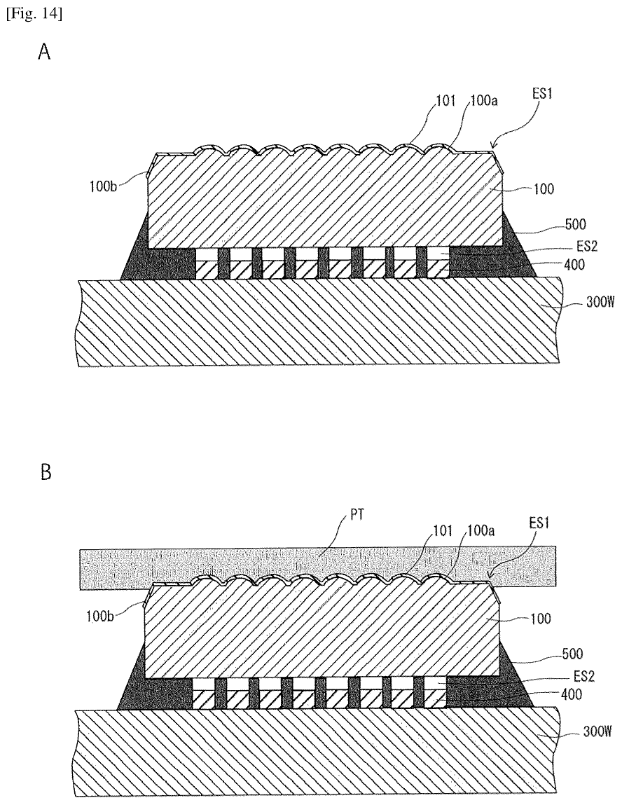

In the next step S6, stealth dicing is performed. Specifically, first, in the wafer 100W, a crack C is formed at the scribe position provided with the tapered groove VT, from the one surface (upper surface) side (opposite to the tapered groove VT). In particular, a laser beam LB (focusing beam) is radiated to the wafer 100W at the scribe position from the one surface (upper surface) side, to form, inside the wafer 100W, a modified layer ML corresponding to a start point of division (see FIG. 10A (cross-sectional view taken along line 10A-10A in FIG. 11), FIG. 10B (partially enlarged view obtained by enlarging a part of FIG. 10A enclosed by an alternate long and short dash line), and FIG. 11 (plan view)). At this time, the crack C extends toward the tapered groove VT, where stress is concentrated, and reaches the bottom portion of the tapered groove VT without substantial bending. Then, the wafer 100W is extended and separated into multiple optical chips OCs corresponding to elements (see FIG. 12A (cross-sectional view taken along line 12A-12A in FIG. 12B), and FIG. 12B (plan view)). When the optical chips OCs are separated from one another, the end portions of the thin film 101 are formed as the chamfered portion 100b, with no dicing tape DT adhering to the end portions. Note that, in step S6, blade dicing may be performed on the wafer 100W to divide and individuate the wafer 100W into the optical chips OCs. Also in this case, by moving a blade toward the tapered groove VT, the cut can be made to reach the bottom portion of the tapered groove VT without substantial bending.

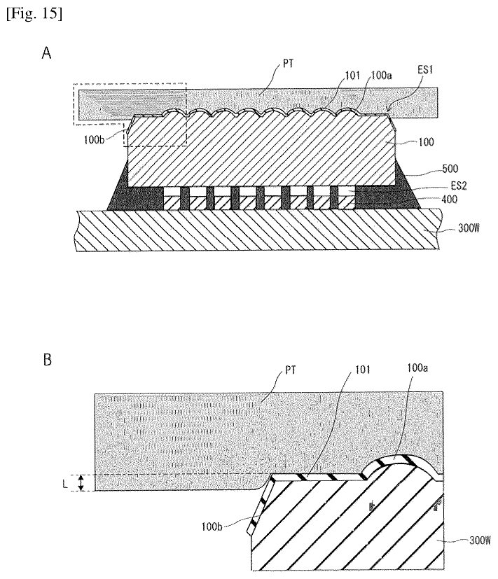

In the next step S7, the optical chips OCs are picked up (see FIG. 13A). Specifically, for example, a manipulator is used to suck and hold each optical chip OC and tear the optical chip OC from the dicing tape DT. In this case, no dicing tape DT adheres to the end portions of the thin film 101 formed at the chamfered portion 100b, and this prevents the peel-off, from the substrate 100, of a portion of the thin film 101 including the end portion thereof as well as chipping of the substrate 100.

In the next step S8, flip chip connection is performed (see FIG. 13B). Specifically, first, the optical chip OC sucked and held by the manipulator is aligned with another wafer 300W in such a manner that the anode electrode 207 and the cathode electrode 208 of the second element constitution section ES2 face the corresponding terminals of the laser driver (to which bumps are attached in advance). Under a predetermined temperature environment, the anode electrode 207 and the corresponding terminal of the laser driver are pressure-bonded via a first bump 400A, and the cathode electrode 208 and the corresponding terminal of the laser driver are pressure-bonded via a second bump 400B.

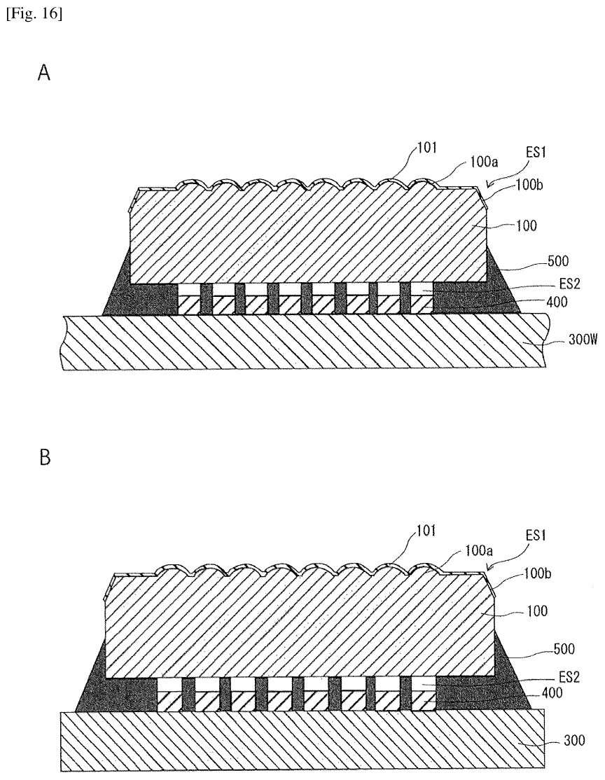

In step S9, the underfill 500 is filled (see FIG. 14A). Specifically, the periphery of the junction between each second element constitution section ES2 of the optical chip OC and the other wafer 300W is filled with the underfill.

In step S10, a protection tape PT is stuck (see FIG. 14B). Specifically, the protection tape PT (adhesive tape used to protect the optical chip OC) is stuck to the surface of the optical chip OC on the thin film 101 side.

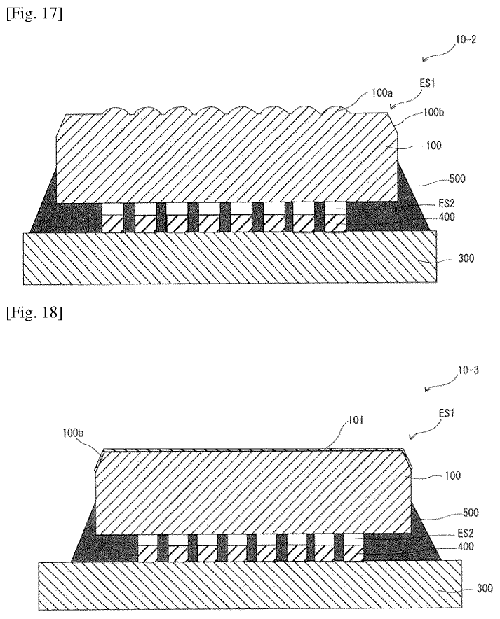

In step S11, the wafer 300W is thinned (see FIG. 15A). Specifically, a back grider or a CMP (Chemical Mechanical Polisher) apparatus is used to grind the back surface (lower surface) of the wafer 300W to thin the wafer 300W. Here, as depicted in FIG. 15B, a partially enlarged view of FIG. 15A, the biting amount L of the protection tape PT in the thickness direction of the wafer 300W with respect to the thin film 101 formed at the chamfered portion 100b is, for example, less than 5 μm, and thus in a case where the chamfered portion 100b has a length of, for example, 5 μm or more in the thickness direction of the wafer 300W of the chamfered portion 100b, the protection tape PT is prevented from adhering to the end portions of the thin film 101.

In step S12, the protection tape PT is released. Specifically, the protection tape PT stuck to the surface of the optical chip OC on the thin film 101 side is released in such a manner as to be rolled up. At this time, the end portions of the thin film 101 formed at the chamfered portion 100b does not adhere to the dicing tape DT, and this prevents the peel-off, from the substrate 100, of a portion of the thin film 101 including the end portion thereof as well as chipping of the substrate 100.

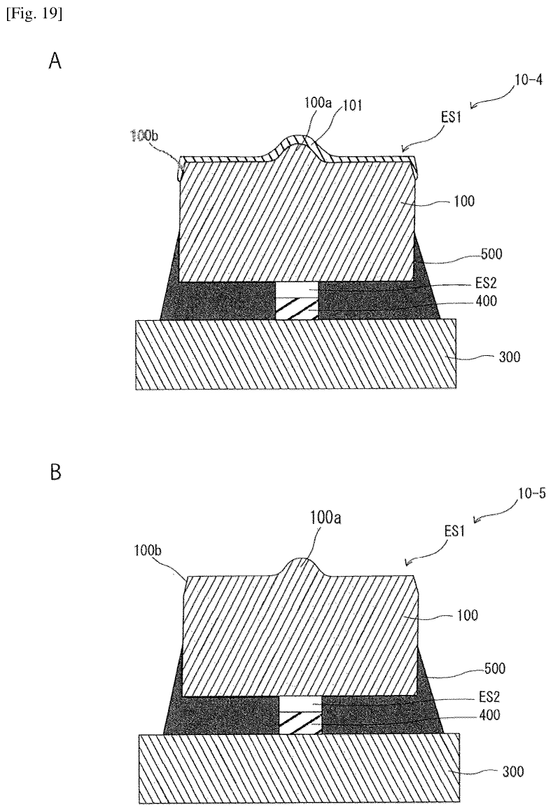

In step S13, blade dicing is performed (see FIG. 16B). Specifically, blade dicing is performed to divide and individuate the wafer 300W into multiple other substrates 300.

### Method for Manufacturing Optical Apparatus According to Comparative Example 1

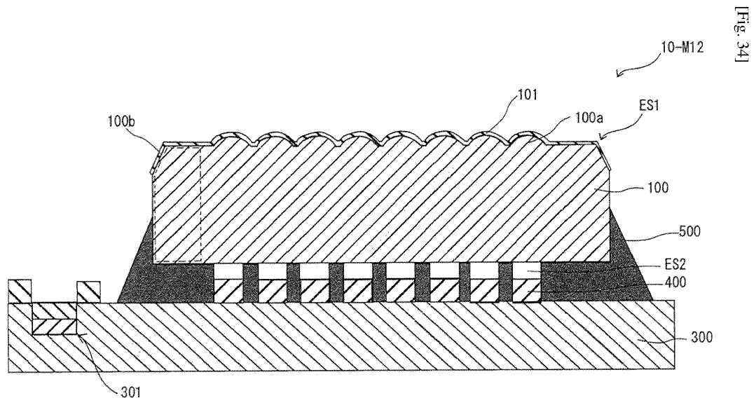

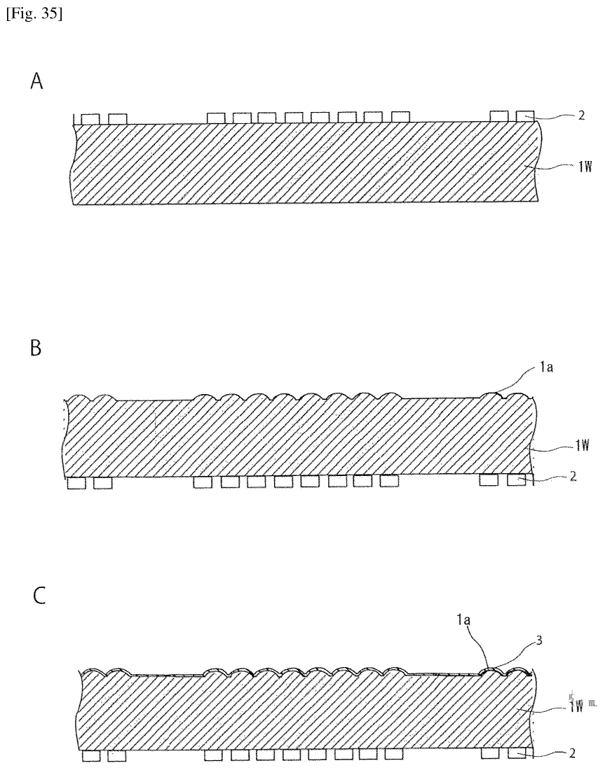

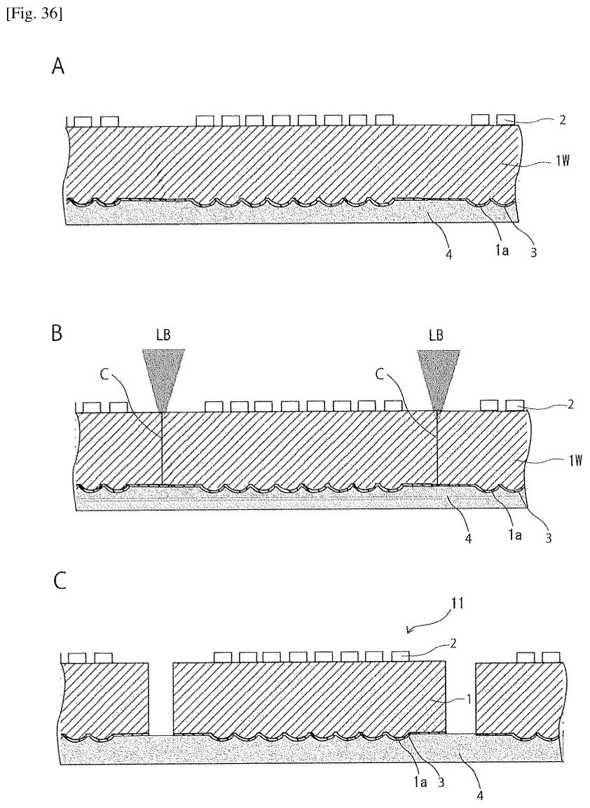

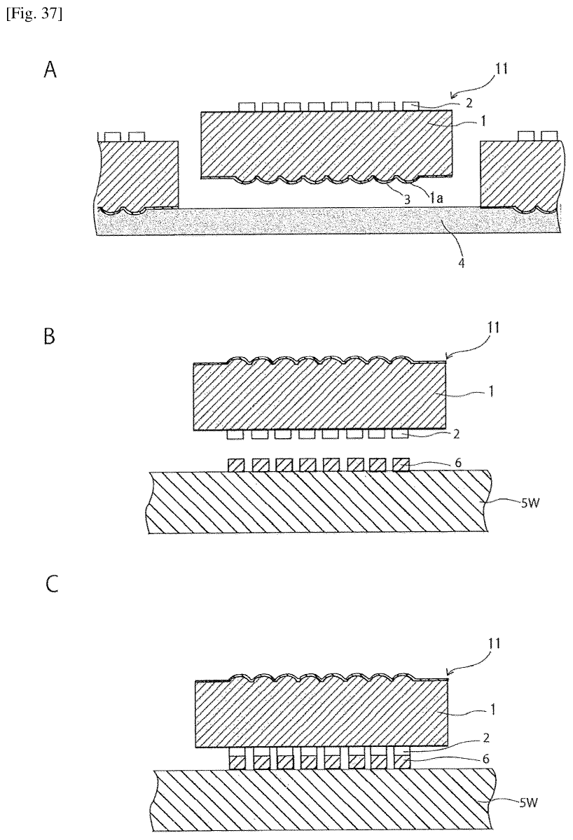

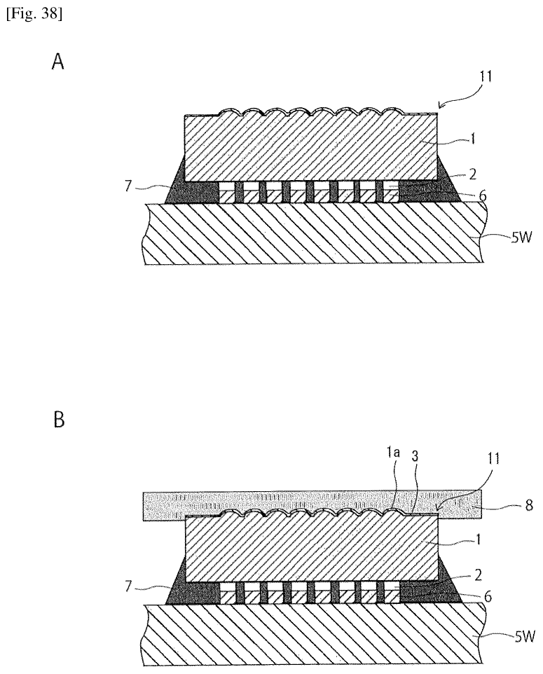

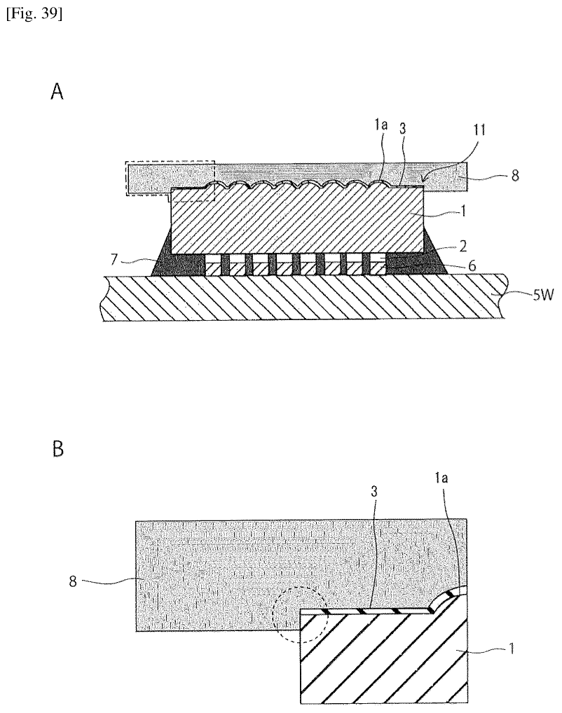

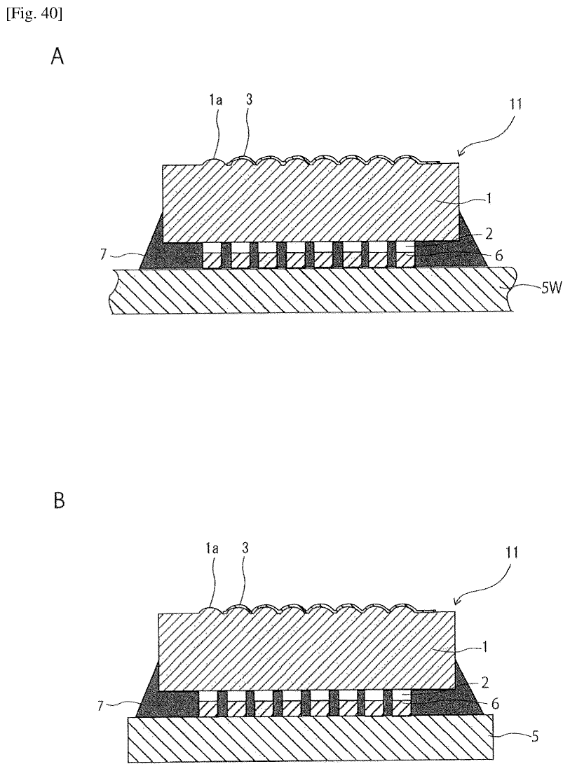

A method for manufacturing an optical apparatus according to Comparative Example 1 will be described in brief with reference to FIGS. 35A to 40B.
(Step 1) Element constitution sections 2 (for example, a VCSEL (except for the substrate) are formed on one surface of the wafer 1W (see FIG. 35A).
(Step 2) The wafer 1W is inverted, and the optical element la (for example, a convex lens structure) is formed on the other surface of the wafer 1W (see FIG. 35B).
(Step 3) A thin film 3 (for example, an anti-reflection film) is formed on the other surface of the wafer 1W (see FIG. 35C).
(Step 4) A dicing tape 4 is stuck to the surface of the wafer 1W on the thin film 3 side (see FIG. 36A).
(Step 5) A laser process of stealth dicing is performed on the wafer 1W to form a crack C (see FIG. 36B). Here, the crack C is formed parallel to the thickness direction of the wafer 1W. That is, each of the substrate 1 into which the wafer 1W bas been divided includes right-angled corners.
(Step 6) A division process of stealth dicing is performed on the wafer 1W to divide and individuate the wafer 1W into multiple optical chips 11 (chip including the substrate 1, the multiple element constitution sections 2, and the thin film 3) (see FIG. 36C). At this time, the dicing tape 4 adheres to the end portions of the thin film 3 of each optical chip 11.
(Step 7) Each optical chip 11 is picked up (see FIG. 37A). At this time, the portion of the thin film 3 including the end portions thereof remains adhering to the dicing tape 4, and the thin film 3 may peel off from the substrate 1.
(Step 8) The element constitution sections 2 of each optical chip 11 are connected (flip flop connection) to another wafer 5W via bumps 6 (conductive bump) (see FIGS. 37B and 37C).
(Step 9) The periphery of the junction between each element constitution section 2 and another wafer 5W is filled with an underfill 7 (see FIG. 38A).
(Step 10) A protection tape 8 is stuck to the surface of the optical chip 11 on the thin film 3 side (see FIG. 38B). At this time, the protection tape 8 adheres to the end portions of the thin film 3.
(Step 11) The other wafer 5W is thinned (see FIG. 39A). Here, as depicted in FIG. 39B, a partially enlarged view of FIG. 39A (enlarged view of a part of FIG. 39A enclosed by an alternate long and short dash line), the protection tape 8 bites into the end portion of the thin film 3 at the corner of the substrate 1 (see the inside of a dashed circle in FIG. 39B)).
(Step 12) The protection tape PT is released. At this time, the portion of the thin film 3 including the end portions thereof may peel off together with the protection tape 8 (see FIG. 40A).
(Step 13) Blade dicing is performed on the other wafer 5W to divide and individuate the wafer 5W into multiple substrates 5 (see FIG. 40B).

When the optical apparatus according to Comparative Example 1 is obtained by the series of steps as described above and the thin film 3 is determined during the subsequent inspection step to have peeled off, the optical apparatus is determined to be defective.

### Method for Manufacturing Optical Apparatus According to Comparative Example 2

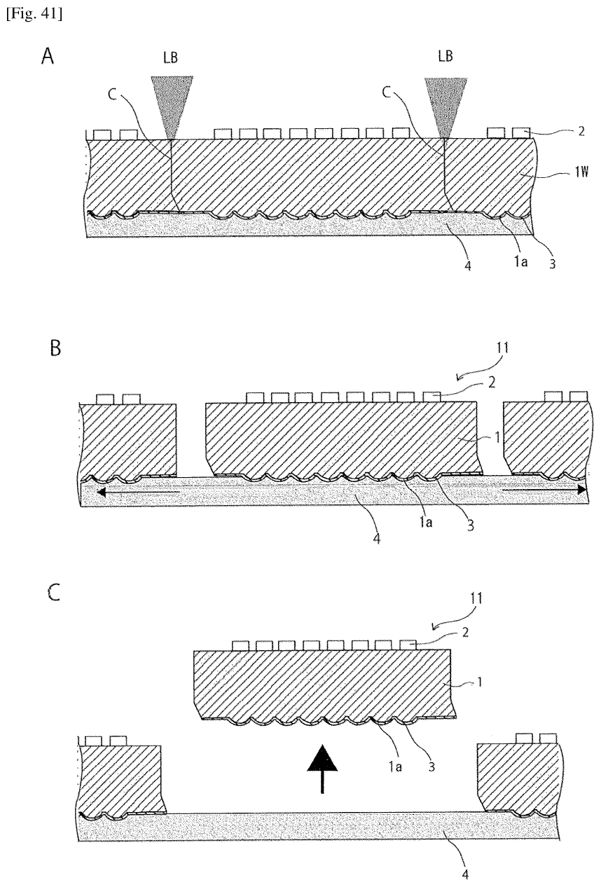

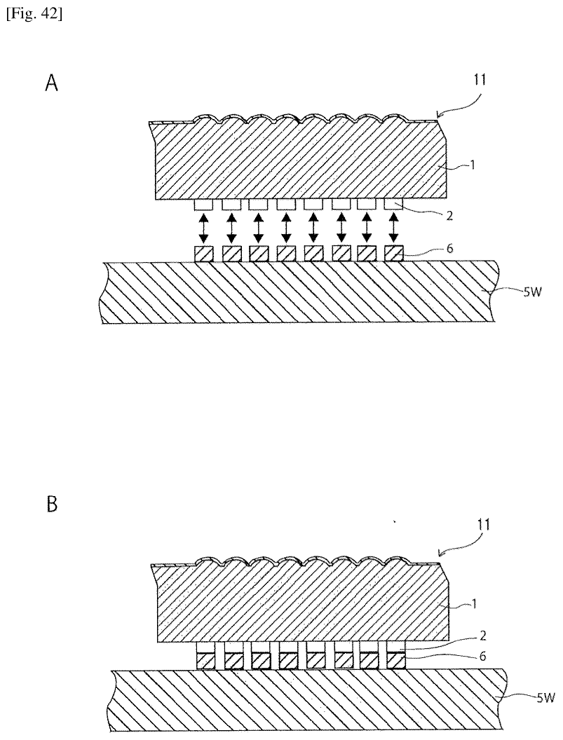

A method for manufacturing an optical apparatus according to Comparative Example 2 will be described in brief with reference to FIGS. 41A to 46B. The method for manufacturing an optical apparatus according to Comparative Example 2 is the same, in steps 1 to 4, as the method for manufacturing an optical apparatus according to Comparative Example 1, and thus, step 5 and subsequent steps will be described.

(Step 5)

A laser process of stealth dicing is performed on the wafer 1W to form a crack C (see FIG. 41A). Here, the crack C initially extends substantially parallel to the thickness direction of the wafer 100W and extends bending along the way. That is, each of the substrates 1 into which the wafer 1W has been divided includes a visor-like portion with a top portion.

(Step 6) A division process of stealth dicing is performed on the wafer 1W to divide and individuate the wafer 1W into multiple optical chips 11 (chip including the substrate 1, the multiple element constitution sections 2, and the thin film 3) (see FIG. 41B). At this time, the dicing tape 4 adheres to the end portions of the thin film 3.

(Step 7) Each optical chip 11 is picked up (see FIG. 41C). At this time, the portion of the thin film 3 including the end portions thereof remains adhering to the dicing tape 4, and the thin film 3 may frequently peel off from the substrate 1.

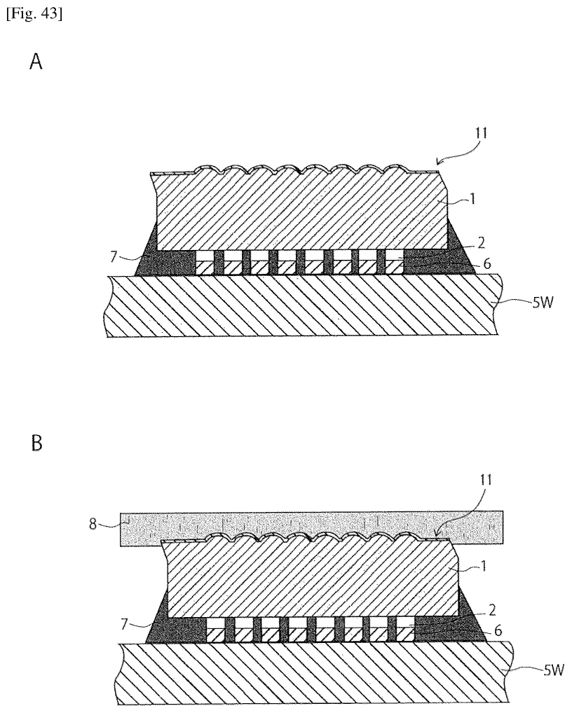

(Step 8) The element constitution sections 2 of each optical chip 11 are connected (flip flop connection) to terminals provided on the other wafer 5W via the bumps 6 (conductive bump) (see FIGS. 42A and 42B).

(Step 9) The periphery of the junction between each element constitution section 2 and another wafer 5W is filled with an underfill 7 (see FIG. 43A).

(Step 10) The protection tape 8 is stuck to the surface of the optical chip 11 on the thin film 3 side (see FIG. 43B). At this time, the protection tape 8 adheres to the end portions of the thin film 3.

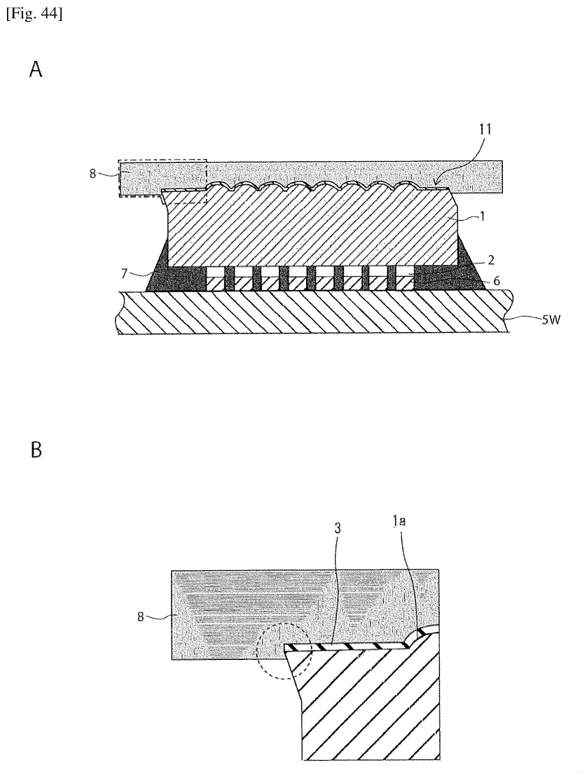

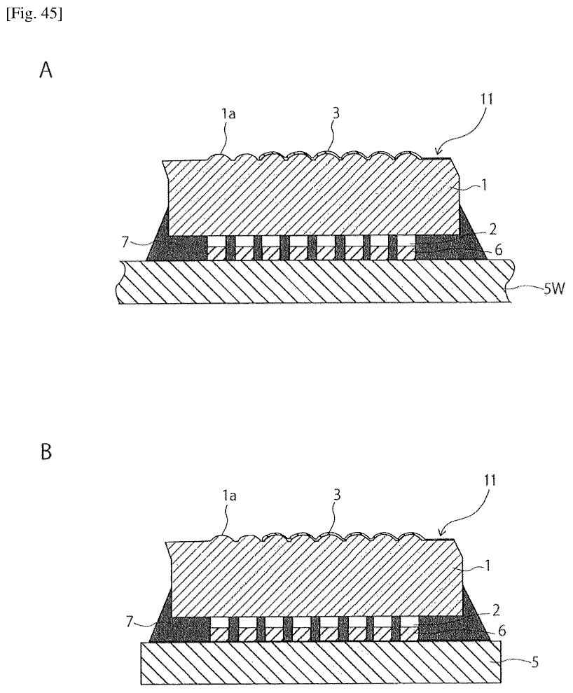

(Step 11) A back surface of the other wafer 5W is ground to thin the other wafer 5W (see FIG. 44A). Here, as depicted in FIG. 44B, a partially enlarged view of FIG. 44A (enlarged view of a part of FIG. 44A enclosed by an alternate long and short dash line), the protection tape 8 bites into the end portion of the thin film 3 at the top portion of the visor portion of the substrate 1 (see the inside of a dashed circle in FIG. 44B)).

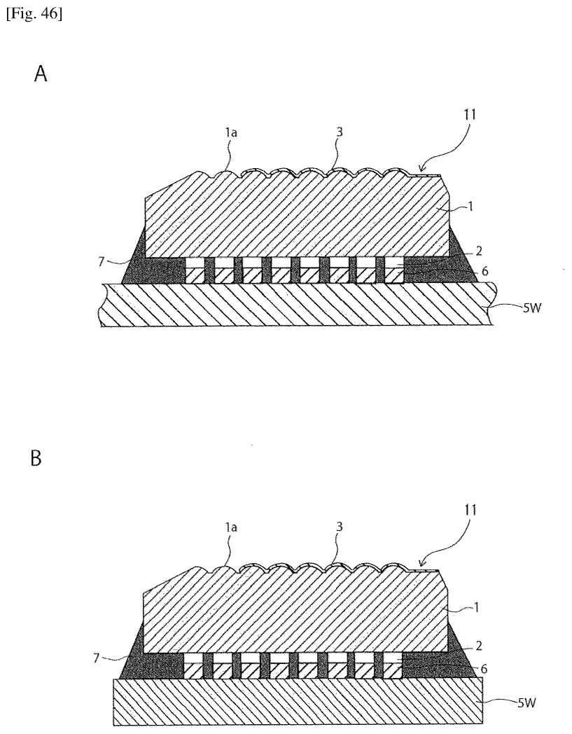

(Step 12) The protection tape PT is released. At this time, frequently, the portion of the thin film 3 including the end portions thereof may be peeled off with the protection tape 8 (see FIG. 45A), and in addition to the peel-off of the portion of the thin film 3 including the end portions thereof, the portion of the substrate 1 including the corner thereof may be broken and chipped (see FIG. 46A).

(Step 13) Blade dicing is performed to divide and individuate the other wafer 5W into multiple substrates 5 (see FIGS. 45B and 46B).

When the optical apparatus according to Comparative Example 2 is obtained by the series of steps as described above and peel-off of the thin film 3 or chipping of the substrate 5 is confirmed during the subsequent inspection step, the optical apparatus is determined to be defective.

### Effects of Optical Apparatus and Method for Manufacturing Optical Apparatus According to Example 1

The effects of the optical apparatus 10-1 according to Example 1 will be described.

The optical apparatus 10-1 according to Example 1 includes the element including the first element constitution section ESI including the substrate 100, and the second element constitution sections ES2 provided on the one surface of the substrate 100, and the substrate 100 includes the chamfered portion 100b at the ends of the other surface (upper surface) side opposite to the one surface (lower surface side) side.

According to the optical apparatus 10-1, an optical apparatus can be provided that can suppress defects in the manufacturing process such as peel-off of the thin film 101 deposited on the substrate 100 and chipping of the substrate 100. As a result, according to the optical apparatus 10-1, an optical apparatus can be provided that can improve productivity (yield).

On the other hand, for example, for the optical apparatuses according to Comparative Examples 1 and 2, there is room for improvement in suppression of defects in the manufacturing process such as peel-off of the thin film 3 deposited on the substrate 1 and chipping of the substrate 1. As a result, for the optical apparatuses according to Comparative Examples 1 and 2, there is room for improvement in enhancing productivity (yield).

The substrate 100 includes the chamfered portion 100b at the ends of the other surface side, and the first element constitution section ES1 is covered by the thin film 101 from the other surface side. Thus, since the end portions of the thin film 101 are formed as the chamfered portion 100b, defects in the manufacturing process can be reliably suppressed, such as peel-off of the thin film 101 formed on the substrate 100 and chipping of the substrate 100.

The substrate 100 includes the chamfered portion 100b at the ends of the other surface side, and the other surface and the chamfered portion 100b are covered by the thin film 101. Thus, since the end portions of the thin film 101 are formed as the chamfered portion 100b, defects in the manufacturing process can be reliably suppressed, such as peel-off of the thin film 101 and chipping of the substrate 100.

The substrate 100 includes the chamfered portion 100b at the ends of the other surface side, the first element constitution section ES1 includes the optical element 100a provided on the other surface of the substrate 100, and at least the optical element 100a and the chamfered portion 100b are covered by the thin film 101. Thus, defects in the manufacturing process can be suppressed, such as peel-off of the thin film 101 covering the optical element 100a and chipping of the optical element 100a.

The chamfered portion 100 b has an inclination angle of 60° or less with respect to the thickness direction of the substrate 100. Thus, in the manufacturing process, the taper angle of the tapered groove VT can be set to 120° or less, contributing to linear formation of the crack C. Note that an excessively large taper angle (for example, greater than 120°) may cause the crack C to bend.

For the chamfered portion 100b, the ratio of the length related to the thickness direction of the substrate 100 to the length related to the in-plane direction of the substrate 100 is 2 or more. Thus, in the manufacturing process, the extending crack C can be made to reliably reach the tapered groove VT.

The length of the chamfered portion 100b related to the thickness direction of the substrate 100 is preferably one-third or less of the thickness of the substrate 100. Thus, breakage of the substrate 100 can be suppressed.

The thin film 101 is preferably an anti-reflection film. This enables prevention of reflection of light from the other surface of the substrate 100, allowing light utilization efficiency to be improved.

Each second element constitution sections ES2 includes the light emitting layer 203. Thus, the element can be made to function as a light emitting array.

Each second element constitution section ES2 includes the first reflector 201 and the second reflector 206 between which the light emitting layer 203 is sandwiched. Thus, the element can be made to function as a surface emitting laser array.

The second element constitution section ES2 includes a mesa including the light emitting layer 203. Thus, the size of the light emitting area (current injection area) of the light emitting layer 203 can be limited to some degree.

The substrate 100 is a semiconductor substrate having conductivity (for example, an n-GaAs substrate). This facilitates generation of an element (for example, a single epitaxial growth step is sufficient), and allows a current path to be formed in the substrate 100.

The optical apparatus 10-1 further includes another substrate 300 joined to the element (for example, the surface emitting laser array). Thus, an optical module can be provided in which the optical apparatus 10-1 includes an element and a driver (drive circuit) integrated together.

The method for manufacturing the optical apparatus 10-1 according to Example 1 includes a step of forming the tapered groove VT on the other surface of the wafer 100W at the scribe position, the wafer 100W being shared by the multiple first element constitution sections ES1 and including the multiple second element constitution sections ES2 provided on the one surface and corresponding to the multiple first element constitution sections ES1, a step of forming a crack C at the scribe position of the wafer 100W from the one surface side, and a step of dividing the wafer 100W provided with the multiple second element constitution sections ES2, at the scribe position, to obtain multiple optical chips OCs including the first and second element constitution sections ES1 and ES2.

According to the method for manufacturing the optical apparatus 10-1, an optical apparatus can be manufactured that can suppress defects such as peel-off of the thin film 101 deposited on the substrate 100 and chipping of the substrate 100. As a result, according to the method for manufacturing the optical apparatus 10-1, productivity (yield) can be improved.

In the step of forming the crack C, the crack C is formed by irradiating the scribe position with laser light from the one surface side of the wafer 100W. This allows the crack C extended by laser light irradiation to reach the tapered groove VT and enables individuation into optical chips OCs including the chamfered portions 100b. Individuation into the optical chips OCs by stealth dicing as described above effectively eliminates disadvantages that are caused by a wet process or a contact process when blade dicing is performed.

In the step of forming the tapered groove VT, etching may be performed on the wafer 100W from the other surface side to form the tapered groove VT and the optical element 100a. This allows the manufacturing process to be simplified.

The method for manufacturing the optical apparatus 10-1 includes a step of forming the thin film 101 on the other surface provided with the tapered groove VT before forming the crack C, a step of sticking the dicing tape DT to the surface of the multiple optical chips OCs on the thin film 101 side after the step of forming the thin film 101 and before the step of forming the crack C, and a step of releasing the multiple optical chips OCs from the dicing tape DT after the step of obtaining. This prevents peel-off of the thin film 101 from each optical chip OC, chipping of the substrate 100, and the like.

The method for manufacturing the optical apparatus 10-1 includes a step of joining the second element constitution sections ES2 of the multiple optical chips OCs to another wafer 300W via the bumps 400 after the step of obtaining, a step of sticking the protection tape PT to the surfaces of the multiple optical chips OCs opposite to the other wafer 300W, a step of grinding and thinning the other wafer 300W, and a step of releasing the protection tape PT from the multiple optical chips OCs. This prevents peel-off of the thin film 101 from each optical chip OC, chipping of the substrate 100, and the like.

The method for manufacturing the optical apparatus 10-1 includes the step of, after the step of releasing, dicing the other wafer 300W to obtain multiple optical apparatuses 10-1 each including a respective one of the multiple optical chips OCs. This enables individuation into optical apparatuses 10-1.

The method for manufacturing the optical apparatus 10-1 includes the step of filling the periphery of the junction between the second element constitution sections ES2 of the multiple optical chips OCs and the other wafer 300W with the underfill 500 after joining. Thus, this produces the effect of reinforcing the junction and the effect of suppressing corrosion of the optical chips OCs and the laser driver.

### 2. Optical Apparatus According to Example 2 According to First Embodiment of Present Technology

An optical apparatus according to Example 2 according to the first embodiment of the present technology will be described below with reference to the drawings. FIG. 17 is a cross-sectional view of an optical apparatus 10-2 according to Example 2 according to the first embodiment of the present technology.

As depicted in FIG. 17, the optical apparatus 10-2 is configured similarly to the optical apparatus 10-1 according to Example 1 except that the substrate 100 is not provided with the thin film 101 as depicted in FIG. 17.

The optical apparatus 10-2 can be manufactured by a manufacturing method similar to the manufacturing method for the optical apparatus 10-1 according to Example 1 except that the step of forming the thin film 101 (step S4 in FIG. 5) is not performed.

The optical apparatus 10-2 is not provided with the thin film 101, and thus does not produce the anti-reflection effect. However, the optical apparatus 10-2 allows the manufacturing process to be simplified and enables suppression of chipping of the substrate 100 (including the optical element 100a) in the manufacturing process.

### 3. Optical Apparatus According to Example 3 According to First Embodiment of Present Technology

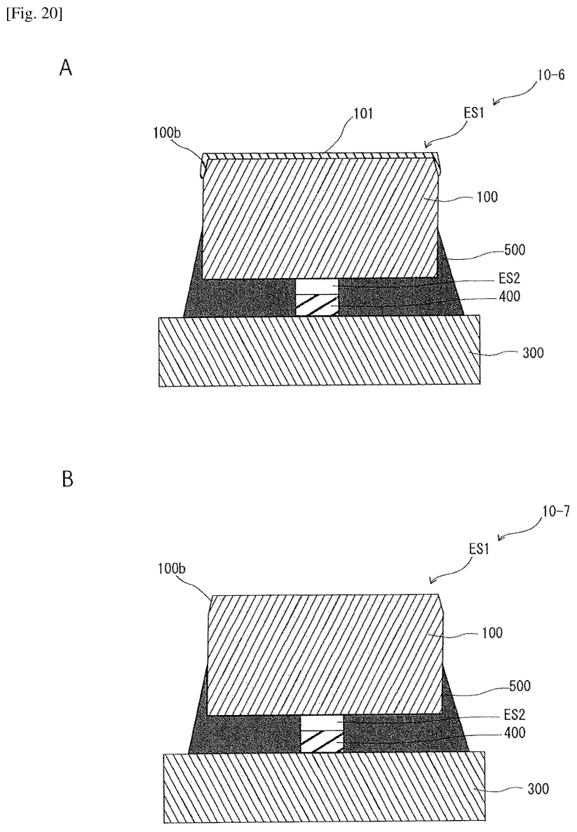

An optical apparatus according to Example 3 according to the first embodiment of the present technology will be described below with reference to the drawings. FIG. 18 is a cross-sectional view of an optical apparatus 10-3 according to Example 3 according to the first embodiment of the present technology.

As depicted in FIG. 18, the optical apparatus 10-3 is configured similarly to the optical apparatus 10-1 according to Example 1 except that the substrate 100 is not provided with the optical element 100a.

The optical apparatus 10-3 can be manufactured by a manufacturing method similar to the manufacturing method for the optical apparatus 10-1 according to Example 1 except that the step of forming the optical element 100a (step S2 in FIG. 5) is not performed.

The optical apparatus 10-3 is not provided with the optical element 100a, and thus does not produce the effect of focusing light emitted from VCSEL. However, the optical apparatus 10-3 allows the manufacturing process to be simplified, and enables suppression of peel-off of the thin film 101, chipping of the substrate 100, and the like in the manufacturing process.

### 4. Optical Apparatus According to Example 4 According to First Embodiment of Present Technology

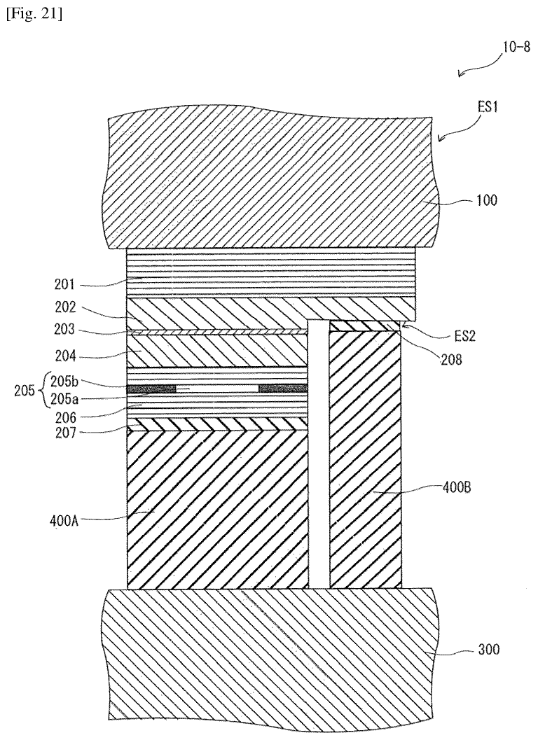

An optical apparatus according to Example 4 according to the first embodiment of the present technology will be described below with reference to the drawings. FIG. 19A is a cross-sectional view of an optical apparatus 10-4 according to Example 4 according to the first embodiment of the present technology.

The optical apparatus 10-4 is configured similarly to the optical apparatus 10-1 According to Example 1 except that the element includes a single VCSEL (light emitting section) as depicted in FIG. 19A.

The optical apparatus 10-4 can be manufactured by a manufacturing method similar to the manufacturing method for the optical apparatus 10-1 according to Example 1 except that a single VCSEL is formed and that the single VCSEL is connected to the other wafer 300W.

According to the optical apparatus 10-4, an optical apparatus can be provided that includes a single light emitting section and that produces effects similar to those of the optical apparatus 10-1 according to Example 1.

### 5. Optical Apparatus According to Example 5 According to First Embodiment of Present Technology

An optical apparatus according to Example 5 according to the first embodiment of the present technology will be described below with reference to the drawings. FIG. 19B is a cross-sectional view of an optical apparatus 10-5 according to Example 5 according to the first embodiment of the present technology.

The optical apparatus 10-5 is configured similarly to the optical apparatus 10-4 according to Example 4 except that the substrate 100 is not provided with the thin film 101 as depicted in FIG. 19B.

The optical apparatus 10-5 can be manufactured by a manufacturing method similar to the manufacturing method for the optical apparatus 10-4 according to Example 4 except that the step of forming the thin film 101 is not performed.

The optical apparatus 10-5 is not provided with the thin film 101, and thus does not produce the anti-reflection effect. However, the optical apparatus 10-5 allows the manufacturing process to be simplified and enables suppression of chipping of the substrate 100 (including the optical element 100a) in the manufacturing process.

### 6. Optical Apparatus According to Example 6 According to First Embodiment of Present Technology

An optical apparatus according to Example 6 according to the first embodiment of the present technology will be described below with reference to the drawings. FIG. 20A is a cross-sectional view of an optical apparatus 10-6 according to Example 6 according to the first embodiment of the present technology.

The optical apparatus 10-6 is configured similarly to the optical apparatus 10-4 according to Example 4 except that the substrate 100 is not provided with the optical element 100a, as depicted in FIG. 20A.

The optical apparatus 10-6 can be manufactured by a manufacturing method similar to the manufacturing method for the optical apparatus 10-4 according to Example 4 except that the step of forming the optical element 100a is not performed.

Compared with the optical apparatus 10-4 according to Example 4, the optical apparatus 10-6 is not provided with the optical element 100a, and thus does not produce the effect of focusing light emitted from VCSEL. However, the optical apparatus 10-6 allows the manufacturing process to be simplified and enables suppression of peel-off of the thin film 101, chipping of the substrate 100, and the like in the manufacturing process.

### 7. Optical Apparatus According to Example 7 According to First Embodiment of Present Technology

An optical apparatus according to Example 7 according to the first embodiment of the present technology will be described below with reference to the drawings. FIG. 20B is a cross-sectional view of an optical apparatus 10-7 according to Example 7 according to the first embodiment of the present technology.

The optical apparatus 10-7 is configured similarly to the optical apparatus 10-6 according to Example 6 except that the substrate 100 is not provided with the thin film 101, as depicted in FIG. 20B.

The optical apparatus 10-7 can be manufactured by a manufacturing method similar to the manufacturing method for the optical apparatus 10-6 according to Example 6 except that the step of forming the thin film 101 is not performed.

Compared with the optical apparatus 10-6 according to Example 6, the optical apparatus 10-7 is not provided with the thin film 101, and thus does not produce the anti-reflection effect. However, the optical apparatus 10-6 allows the manufacturing process to be simplified and enables suppression of chipping of the substrate 100 (including the optical element 100a) in the manufacturing process.

### 8. Optical Apparatus According to Example 8 According to First Embodiment of Present Technology

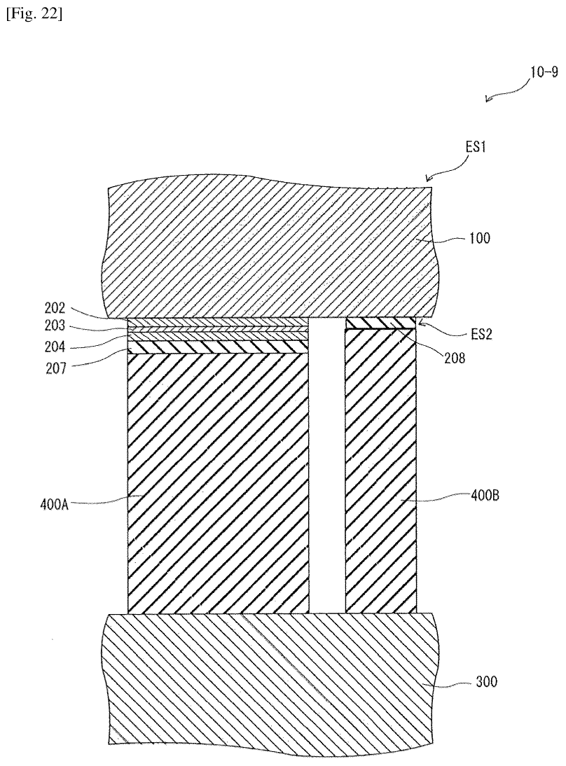

An optical apparatus according to Example 8 according to the first embodiment of the present technology will be described below with reference to the drawings. FIG. 21 is a partially enlarged view (corresponding to FIG. 3) of an optical apparatus 10-8 according to Example 8 according to the first embodiment of the present technology.

The optical apparatus 10-8 according to Example 8 is configured similarly to the optical apparatus 10-1 according to Example 1 except that each VCSEL has an intracavity structure as depicted in FIG. 21.

In the second element constitution section ES2 of the optical apparatus 10-8, a mesa includes a part (lower portion) of the first clad layer 202, the light emitting layer 203, the second clad layer 204, and the second reflector 206 containing the oxidized constriction layer 205. The cathode electrode 208 is provided in the area around the mesa in the other part (upper portion) of the first clad layer 202.

The optical apparatus 10-8 can include an undoped semiconductor substrate (for example, an i-GaAs substrate) as the substrate 100. The optical apparatus 10-8 can include an undoped compound semiconductor (for example, i-AlGaAs) as a material for the first reflector 201.

The optical apparatus 10-8 can be manufactured by a manufacturing method similar to the manufacturing method for the optical apparatus 10-1 according to Example 1 except that the bottom surface of the mesa is positioned in the first clad layer 202 when the second element constitution section ES2 is formed.

According to the optical apparatus 10-8, an optical apparatus can be provided that produces effects similar to those of the optical apparatus 10-1 according to Example 1 and that can reduce the series resistance of each VCSEL.

Note that, in the second element constitution section ES2 of the optical apparatus 10-8, a mesa may include a part (lower portion) of the first reflector 201, the first clad layer 202, the light emitting layer 203, the second clad layer 204, and the second reflector 206 containing the oxidized constriction layer 205. In this case, the cathode electrode 208 may be provided in the area around the mesa in the other part (upper portion) of the first reflector 201.

### 9. Optical Apparatus According to Example 9 According to First Embodiment of Present Technology

An optical apparatus according to Example 9 according to the first embodiment of the present technology will be described below with reference to the drawings. FIG. 22 is a partially enlarged view (corresponding to FIG. 3) of an optical apparatus 10-9 according to Example 9 according to the first embodiment of the present technology.

The optical apparatus 10-9 according to Example 9 is configured similarly to the optical apparatus 10-1 according to Example 1 except that each light emitting section is a LED (light emitting diode) as depicted in FIG. 22. That is, the optical apparatus 10-9 includes a LED array as an element.

In the second element constitution section ES2 of the optical apparatus 10-9, the mesa includes the light emitting layer 203 and the first and second clad layers 202 and 204 that sandwich the light emitting layer 203 in an up-down direction.

The optical apparatus 10-9 can be manufactured by a manufacturing method similar to the manufacturing method for the optical apparatus 10-1 according to Example 1 except that the first and second reflectors 201 and 206 are not deposited when the second element constitution section ES2 is formed.

According to the optical apparatus 10-9, an optical apparatus can be provided that includes a LED array and that produces effects similar to the effects of the optical apparatus 10-1 according to Example 1.

### 10. Optical Apparatus According to Example 10 According to First Embodiment of Present Technology

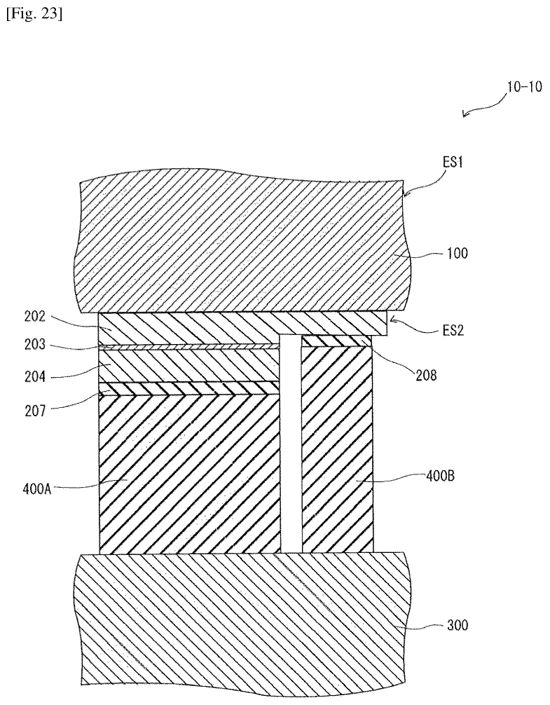

An optical apparatus according to Example 10 according to the first embodiment of the present technology will be described below with reference to the drawings. FIG. 23 is a partially enlarged view (corresponding to FIG. 3) of an optical apparatus 10-10 according to Example 10 according to the first embodiment of the present technology.

The optical apparatus 10-10 according to Example 10 is configured similarly to the optical apparatus 10-9 according to Example 9 except that each LED has a structure similar to the intracavity structure as depicted in FIG. 23.

In the second element constitution section ES2 of the optical apparatus 10-10, the mesa includes a part (lower portion) of the first clad layer 202, the light emitting layer 203, and the second clad layer 204. The cathode electrode 208 is provided in the area around the mesa in the other part (upper portion) of the first clad layer 202.

In the optical apparatus 10-10, an undoped semiconductor substrate (for example, an i-GaAs substrate) can be used as the substrate 100. In the optical apparatus 10-8, an undoped compound semiconductor (for example, i-AlGaAs) can also be used as material for the first reflector 201.

The optical apparatus 10-10 can be manufactured by a manufacturing method similar to the manufacturing method for the optical apparatus 10-9 according to Example 9 except that the bottom surface of the mesa is positioned in the first clad layer 202 when the second element constitution section ES2 is formed.

According to the optical apparatus 10-10, an optical apparatus can be provided that produces effects similar to those of the optical apparatus 10-9 according to Example 9 and that can reduce the series resistance of each light emitting section (each LED).

### 11. Optical Apparatus According to Example 11 According to First Embodiment of Present Technology

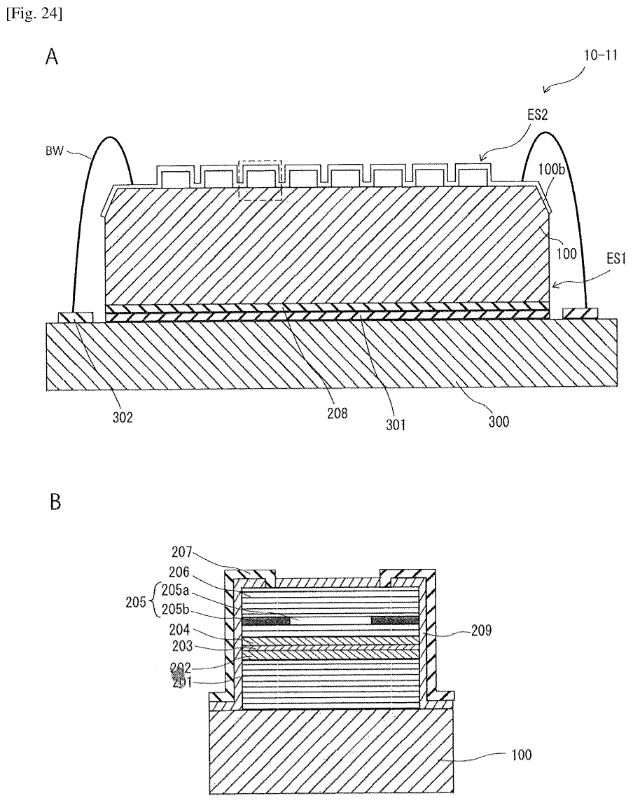

An optical apparatus according to Example 11 according to the first embodiment of the present technology will be described below with reference to the drawings. FIG. 24A is a cross-sectional view of an optical apparatus 10-11 according to Example 11 according to the first embodiment of the present technology. FIG. 24B is a partially enlarged view of FIG. 24A (enlarged view of a part of FIG. 24A enclosed by an alternate long and short dash line).

In the optical apparatus 10-11 according to Example 11, an element including the first and second element constitution sections ES1 and ES2 is connected junction up to the other substrate 300, as depicted in FIG. 24A.

In the optical apparatus 10-11, the substrate 100 (for example, an n-GaAs substrate) includes the chamfered portion 100b at the ends of the one surface (upper surface) side provided with the multiple second element constitution sections ES2.

In the optical apparatus 10-11, the mesas of the multiple second element constitution sections ES2 are provided, in common, with an insulating film 209 as a thin film and the anode electrode 207 as a thin film (see FIGS. 24A and 24B). End portions of the anode electrode 207 and the insulating film 209 are provided on the chamfered portion 100b. The anode electrode 207 includes, on a central portion of each mesa, an opening used as an emission port.

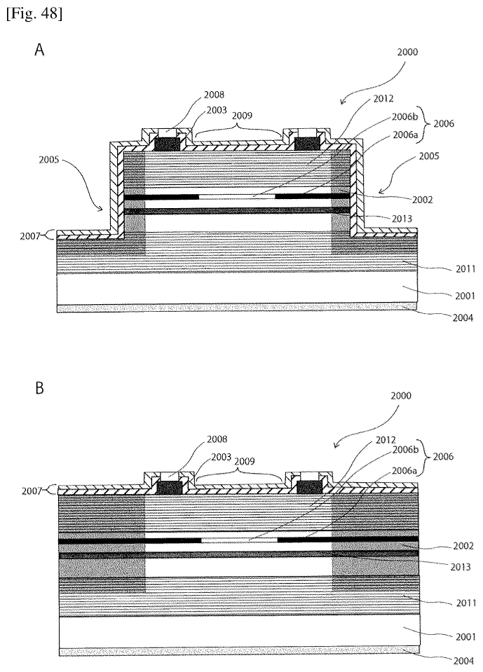

At a position near the chamfered portion 100b of the one surface of the substrate 100, the anode electrode 207 is connected by a bonding wire BW to a terminal 302 provided on the other substrate 300. In an example embodiment, a bonding wire and/or an electrode are provided as a thin film 101 on the upper surface of the substrate 100, for example, as illustrated in an embodiment of FIG. 48, such that the groove surface or chamfered portion 100b are covered by the bonding wire and/or the electrode. In an example, the bonding wire and/or the electrode are preferably an Au thin film. Also, the thin film 101 may comprise multiple layers, such as an anode electrode 207 and an insulating film 209.

In the optical apparatus 10-11, the cathode electrode 208 is solidly provided on the other surface (lower surface) side of the substrate 100. The cathode electrode 208 is joined to a terminal 301 (terminal of the laser driver on the negative electrode side) provided on the other substrate 300.

In the process of manufacturing the optical apparatus 10-11, a dicing tape and a protection tape are stuck to the surface of the optical chip on the side of the multiple second element constitution sections ES2.

According to the optical apparatus 10-11, an optical apparatus can be provided that can suppress defects such as peel-off of the anode electrode 207 and the insulating film 209 and chipping of the substrate 100.

### 12. Optical Apparatus According to Example 1 According to Second Embodiment of Present Technology

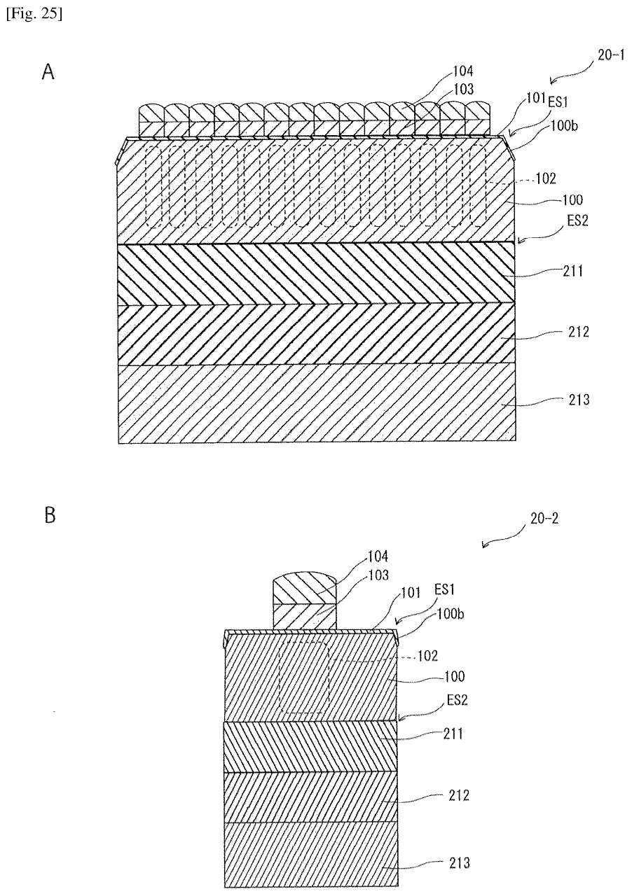

An optical apparatus according to Example 1 according to the second embodiment of the present technology will be described below with reference to the drawings. FIG. 25A is a cross-sectional view of an optical apparatus 20-1 according to Example 1 according to the second embodiment of the present technology.

An element of the optical apparatus 20-1 is a solid image sensor (image sensor), as depicted in FIG. 25A. Multiple photoelectric converting element 102 (for example, photodiodes) is provided in the substrate 100 (semiconductor substrate, for example, Si substrate). The multiple photoelectric converting elements 102 is two-dimensionally arranged (for example, matrix arrangement, staggered arrangement, or the like) on the substrate 100 in the in-plane direction. The chamfered portion 100b is provided at the ends of the one surface side (upper surface side) of the substrate 100. The one surface (upper surface) and chamfered portion 100b of the substrate 100 are covered by the thin film 101 (for example, an anti-reflection film). Color filters 103 and micro lenses 104 corresponding to the photoelectric converting elements 102 are provided on the thin film 101 in this order. That is, the solid image sensor of the optical apparatus 20-1 includes a pixel array including multiple pixels two-dimensionally arranged and each including the photoelectric converting element 102, the color filter 103, and the micro lens 104. In the optical apparatus 20-2, the first element constitution section ES1 includes the substrate 100, the color filter 103, and the micro lens 104. Note that at least one of the color filter 103 and the micro lens 104 may be omitted from each pixel. Here, the solid image sensor is illustrated as an area sensor but may be a linear sensor. An inter-pixel light shielding film may be provided between adjacent pixels.

A first wiring layer 211, a second wiring layer 212, and a substrate 213 (for example, a semiconductor substrate such as an Si substrate including a built-in logic circuit and a built-in memory circuit) constituting the second element constitution section ES2 are laminated on the other surface (lower surface) of the substrate 100 from the other surface side.

The first wiring layer 211 is electrically connected to the substrate 100, for example, via a via. The second wiring layer 212 is electrically connected to the substrate 213, for example, via a via. The first and second wiring layers 211 and 212 are electrically connected, for example, by metal bonding.

In the optical apparatus 20-1, in the manufacturing process, a dicing tape and a protection tape are stuck to the surface of the optical chip on the side of the first element constitution section ES1.

According to the optical apparatus 20-1, an optical apparatus can be provided that includes the solid image sensor and that can suppress defects such as peel-off of the thin film 101 deposited on the substrate 100 and chipping of the substrate 100.

### 13. Optical Apparatus According to Example 2 According to Second Embodiment of Present Technology

An optical apparatus according to Example 2 according to the second embodiment of the present technology will be described below with reference to the drawings. FIG. 25B is a cross-sectional view of an optical apparatus 20-2 according to Example 2according to the second embodiment of the present technology.

The optical apparatus 20-2 is configured similarly to the optical apparatus 20-1 according to Example 1 except that the optical apparatus 20-2 includes a solid image sensor including a single pixel.

The optical apparatus 20-2 can be manufactured by a manufacturing method similar to the manufacturing method for the optical apparatus 20-1 according to Example 1.

According to the optical apparatus 20-2, an optical apparatus can be provided that includes a solid image sensor including a single pixel and that produces effects similar to those of the optical apparatus 20-1 according to Example 1.

### 14. Optical Apparatus According to Example 3 According to Second Embodiment of Present Technology

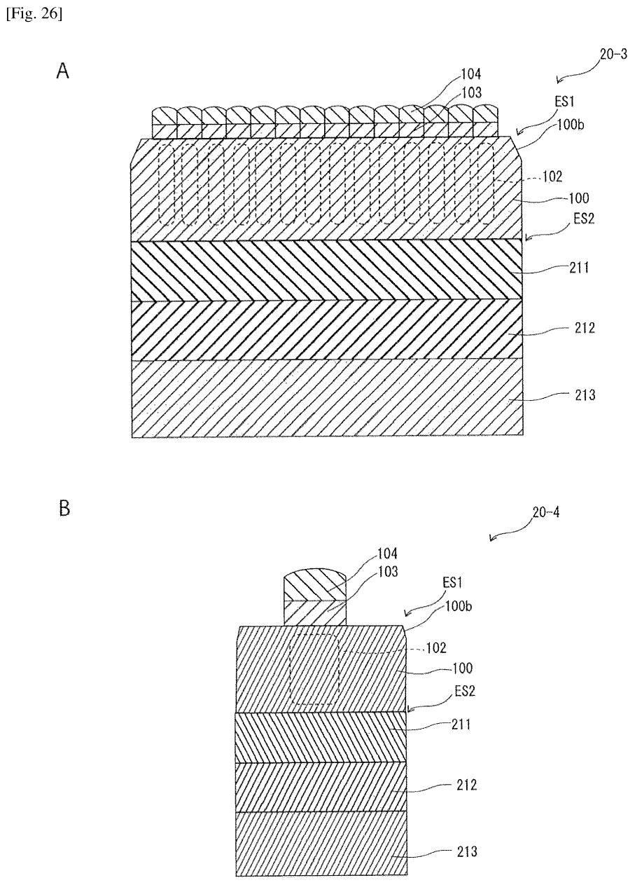

An optical apparatus according to Example 3 according to the second embodiment of the present technology will be described below with reference to the drawings. FIG. 26A is a cross-sectional view of an optical apparatus 20-3 according to Example 3 according to the second embodiment of the present technology.

The optical apparatus 20-3 is configured similarly to the optical apparatus 20-1 according to Example 1 except that the substrate 100 is not provided with the thin film 101.

The optical apparatus 20-3 can be manufactured by a manufacturing method similar to the manufacturing method for the optical apparatus 20-1 according to Example 1 except that the substrate 100 is not provided with the thin film 101.

The optical apparatus 20-3 is not provided with the thin film 101, and thus does not produce the anti-reflection effect. However, the optical apparatus 20-3 allows the manufacturing process to be simplified and enables suppression of chipping of the substrate 100 in the manufacturing process.

### 15. Optical Apparatus According to Example 4 According to Second Embodiment of Present Technology

An optical apparatus according to Example 4 according to the second embodiment of the present technology will be described below with reference to the drawings. FIG. 26B is a cross-sectional view of an optical apparatus 20-4 according to Example 4 according to the second embodiment of the present technology.

The optical apparatus 20-4 is configured similarly to the optical apparatus 20-3 according to Example 3 except that the optical apparatus 20-4 includes a solid image sensor including a single pixel.

The optical apparatus 20-4 can be manufactured by a manufacturing method similar to the manufacturing method for the optical apparatus 20-2 according to Example 2 except that the substrate 100 is not provided with the thin film 101.

According to the optical apparatus 20-4, an optical apparatus can be provided that includes a solid image sensor including a single pixel and that produces effects similar to those of the optical apparatus 20-3 according to Example 3.

### 16. Modifications of Present Technology

Modifications may be made to the present technology without being limited by the examples of the above-described embodiments.

### Modification of Chamfered Portion 100b (1)

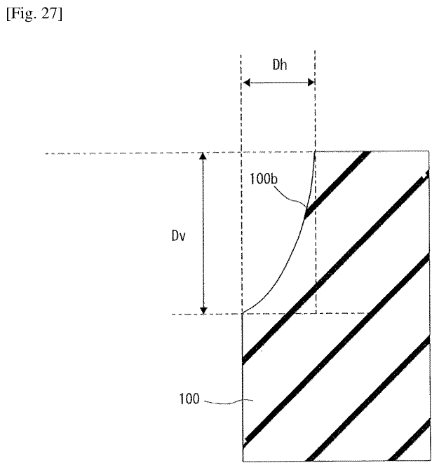

For example, in each example of each of the above-described embodiments, the chamfered portion 100b may be a curved surface that is projection downward as depicted in FIG. 27. In this case, in the manufacturing process, a curved surface in FIG. 27 is obtained by forming a tapered groove in the substrate 100 in such a manner that the tapered groove includes an inner wall surface corresponding to a curved surface projection downward (curved surface corresponding to a combination of the curved surface in FIG. 27 and a curved surface in a symmetric relation with the curved surface in FIG. 27).

### Modification of Chamfered Portion 100b (2)

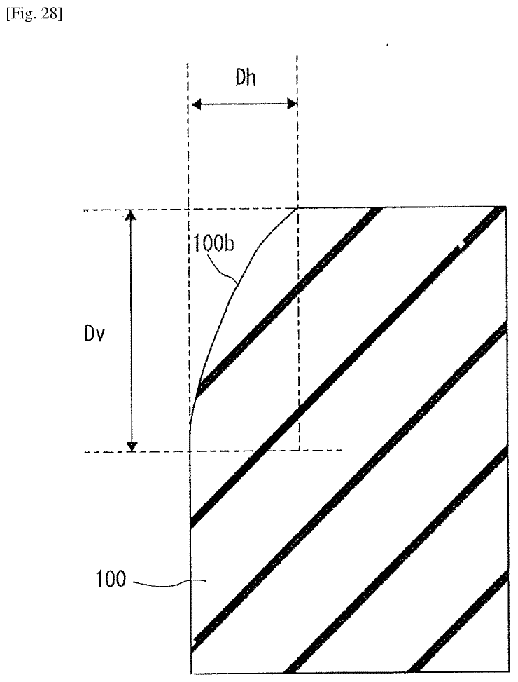

For example, in each example of each of the above-described embodiments, the chamfered portion 100b may be a curved surface that is projection upward as depicted in FIG. 28. In this case, in the manufacturing process, a curved surface in FIG. 28 is obtained by forming a tapered groove in the substrate 100 in such a manner that the tapered groove includes an inner wall surface corresponding to a curved surface projection upward (curved surface corresponding to a combination of the curved surface in FIG. 28 and a curved surface in a symmetric relation with the curved surface in FIG. 28).

### Optical Apparatus According to Modification 1 According to First Embodiment

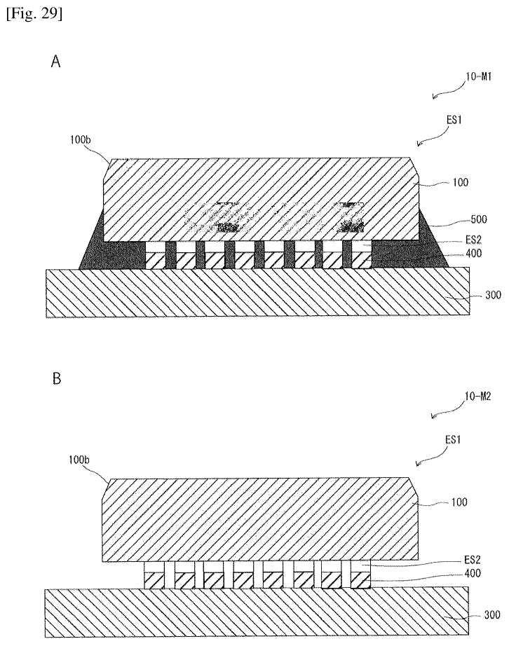

An optical apparatus 10-M1 according to Modification 1 according to the first embodiment, depicted in FIG. 29A, is configured similarly to the optical apparatus 10-3 according to Example 3 according to the first embodiment (see FIG. 18) except that the substrate 100 is not covered by the thin film 101.

### Optical Apparatus According to Modification 2 According to First Embodiment

An optical apparatus 10-M2 according to Modification 2 according to the first embodiment, depicted in FIG. 29B, is configured similarly to the optical apparatus 10-M1 according to Modification 1 except that the underfill 500 is not provided.

### Optical Apparatus According to Modification 3 According to First Embodiment

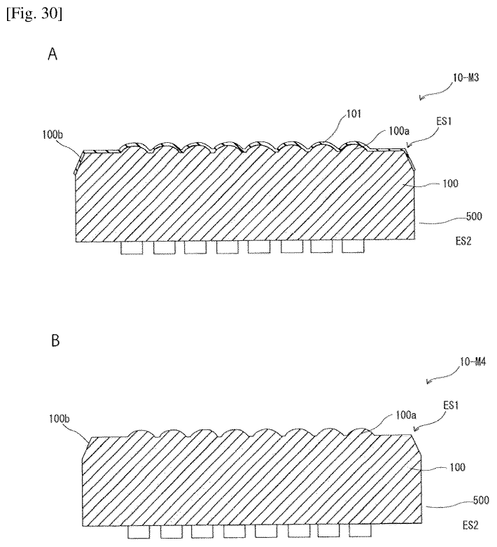

An optical apparatus 10-M3 according to Modification 3 according to the first embodiment, depicted in FIG. 30A, is configured similarly to the optical apparatus 10-1 according to Example 1 according to the first embodiment (see FIG. 1) except that the other substrate 300, the bump 400, and the underfill 500 are omitted.

### Optical Apparatus According to Modification 4 According to First Embodiment

An optical apparatus 10-M4 according to Modification 4 according to the first embodiment, depicted in FIG. 30B, is configured similarly to the optical apparatus 10-2 according to Example 2 according to the first embodiment (see FIG. 17) except that the other substrate 300, the bump 400, and the underfill 500 are omitted.

### Optical Apparatus According to Modification 5 According to First Embodiment

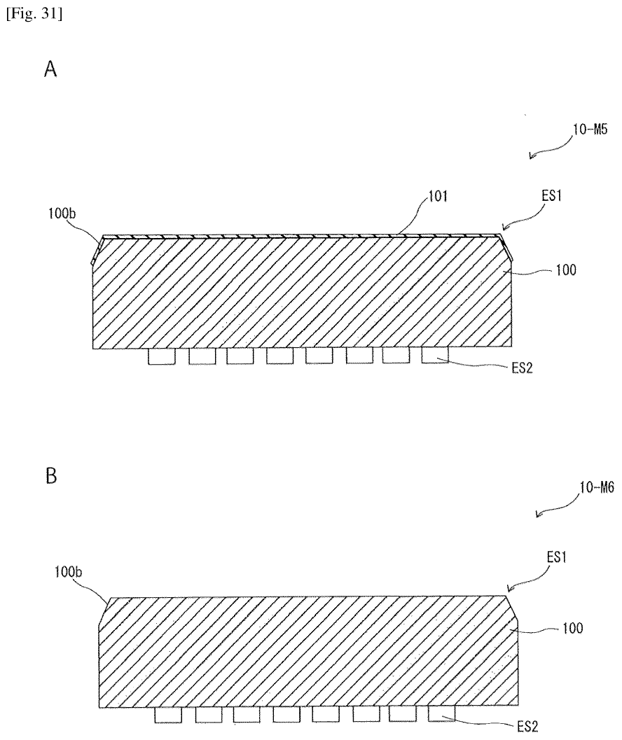

An optical apparatus 10-M5 according to Modification 5 according to the first embodiment, depicted in FIG. 31A, is configured similarly to the optical apparatus 10-3 according to Example 3 according to the first embodiment (see FIG. 18) except that the other substrate 300, the bump 400, and the underfill 500 are omitted.

### Optical Apparatus According to Modification 6 According to First Embodiment

An optical apparatus 10-M6 according to Modification 6 according to the first embodiment, depicted in FIG. 31B, is configured similarly to the optical apparatus 10-M1 according to Modification 1 (see FIG. 29A) except that the other substrate 300, the bump 400, and the underfill 500 are omitted.

### Optical Apparatus According to Modification 7 According to First Embodiment

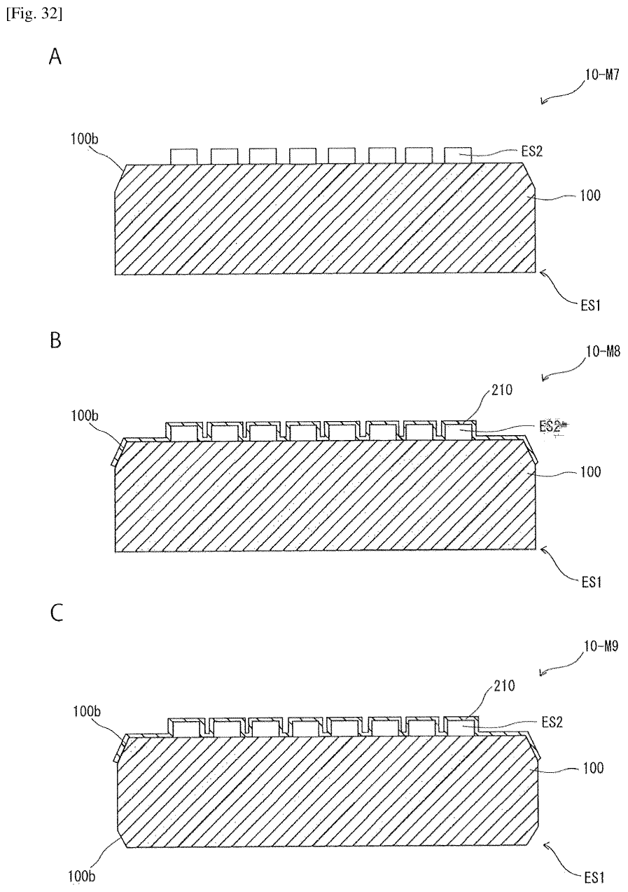

An optical apparatus 10-M7 according to Modification 7 according to the first embodiment, depicted in FIG. 32A, is configured similarly to the optical apparatus 10-M6 according to Modification 6 (see FIG. 31B) except that the substrate 100 includes the chamfered portion 100b at the ends of the one surface (upper surface) side provided with the second element constitution sections ES2.

### Optical Apparatus According to Modification 8 According to First Embodiment

An optical apparatus 10-M8 according to Modification 8 according to the first embodiment, depicted in FIG. 32B, is configured similarly to the optical apparatus 10-M7 according to Modification 7 (see FIG. 32A) except that the one surface (upper surface), the chamfered portion 100b, and the second element constitution sections ES2 of the substrate 100 are covered by a thin film 210 including an insulating film and an anode electrode provided on the insulating film. The anode electrode of the thin film 210 may be provided with an opening used as an emission port.

### Optical Apparatus According to Modification 9 According to First Embodiment

An optical apparatus 10-M9 according to Modification 9 according to the first embodiment, depicted in FIG. 32C, is configured similarly to the optical apparatus 10-M8 according to Modification 8 (see FIG. 32B) except that the substrate 100 also includes the chamfered portion 100b at the ends of the other surface (lower surface) side.

### Optical Apparatus According to Modification 10 According to First Embodiment

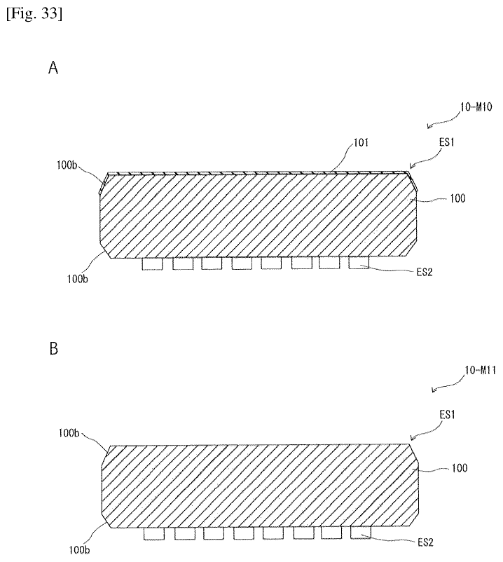

An optical apparatus 10-M10 according to Modification 10 according to the first embodiment, depicted in FIG. 33A, is configured similarly to the optical apparatus 10-M5 according to Modification 5 (see FIG. 31A) except that the substrate 100 also includes the chamfered portion 100b at the ends of the one surface (lower surface) side provided with the second element constitution sections ES2.

### Optical Apparatus According to Modification 11 According to First Embodiment

An optical apparatus 10-M11 according to Modification 11 according to the first embodiment, depicted in FIG. 33B, is configured similarly to the optical apparatus 10-M6 according to Modification 6 (see FIG. 31B) except that the substrate 100 also includes the chamfered portion 100b at the ends of the one surface (lower surface) side provided with the second element constitution sections ES2.

### Optical Apparatus According to Modification 12 According to First Embodiment

An optical apparatus 10-M12 according to Modification 11 according to the first embodiment, depicted in FIG. 34, constitutes a distance measuring apparatus. The optical apparatus 10-M12 is configured substantially similarly to the optical apparatus 10-1 according to Example 1 according to the first embodiment except that the optical apparatus 10-M12 includes a light receiving element 301 provided on the other substrate 300.

In the optical apparatus 10-M12, as an example, the other substrate is a Ge substrate provided with a laser driver and an IC including a light receiving circuit. The light receiving circuit includes, for example, an A/D converter, a TOF (Time Of flight) calculating section, and the like.

As an example, the light receiving element 301 is provided in such a manner that a light receiving surface is exposed in a hole portion provided around an implementation area of a surface of the other substrate 300 in which area an element (surface emitting laser array) is implemented. As an example, the light receiving element 301 is an APD (Avalanche Photo Diode).

The optical apparatus 10-M12 can be manufactured by a manufacturing method similar to the manufacturing method for the optical apparatus 10-1 according to Example 1 according to the first embodiment except that the other substrate 300 is provided with an IC and the light receiving element 301.

According to the optical apparatus 10-M12, a high-performance TOF module can be provided that includes a surface emitting laser array and the light receiving element 301 producing effects similar to those of the optical apparatus 10-1 according to Example 1 according to the first embodiment.

### Modification of Surface Emitting Laser of Optical Apparatus According to Present Technology

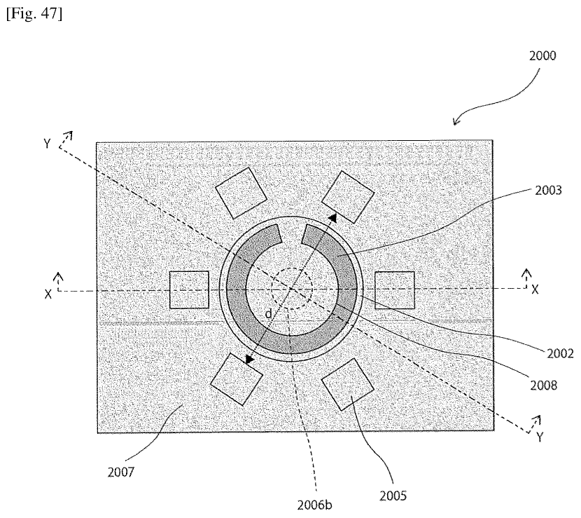

FIG. 47 is a plan view depicting a surface emitting laser 2000 corresponding to a modification of the surface emitting laser of the optical apparatus according to the present technology. FIG. 48A is a cross-sectional view taken along line X-X in FIG. 47. FIG. 48B is a cross-sectional view taken along line Y-Y in FIG. 47.

Components of the surface emitting laser 2000 are laminated on a substrate 2001. The substrate 2001 can include a semiconductor, for example, GaAs, InGaAs, InP, InAsP, or the like.

The surface emitting laser 2000 includes a protection area 2002 (transmissive gray areas in FIGS. 48A and 48B). As depicted in FIG. 47, the protection area 2002 is circular as seen in plan view, but may have another shape, for example, an ellipse, a polygon, or the like. The protection area 2002 is not limited to a particular shape. The protection area 2002 includes a material that causes electric separation, and is, for example, an area in which ion is implanted.

Furthermore, as depicted in FIGS. 48A and 48B, the surface emitting laser 2000 includes a first electrode 2003 and a second electrode 2004. As depicted in FIG. 47, the first electrode 2003 is shaped like a ring with discontinuous portions (intermittent portions), that is, a split ring, as seen in plan view. However, the first electrode 2003 is not limited to a particular shape. As depicted in FIGS. 48A and 48B, the second electrode 2004 is in contact with the substrate 2001. The first electrode 2003 and the second electrode 2004 include a conductive material, for example, Ti, Pt, Au, AuGeNi, PdGeAu, or the like. Each of the first electrode 2003 and the second electrode 2004 may have a single-layer structure or a laminate structure.

Furthermore, the surface emitting laser 2000 includes a trench 2005 provided around the protection area 2002. FIG. 47 depicts a structure in which a trench 2005 that is rectangular as seen in plan view is provided at six points, as an example. However, the number of trenches 2005 and the shape of the trench 2005 in plan view are not limited to particular ones. The trench 2005 is an opening used to form an oxidized constriction layer 2006 (including an oxidized area 2006a and a non-oxidized area 2006b). In the process of manufacturing the surface emitting laser 2000, the oxidized area 2006a of the oxidized constriction layer 2006 is formed by feeding high-temperature steam via the trench 2005. For example, the oxidized area 2006a is Al₂O₃ formed as a result of oxidization of an AlAs or AlGaAs layer. Any dielectric may be embedded in the trench 2005 after the step of forming the oxidized constriction layer 2006. Additionally, surface coating may be performed using a dielectric film.

Furthermore, the surface emitting laser 2000 includes a dielectric opening 2008 (contact hole) provided in the dielectric layer 2007 on the first electrode 2003. The dielectric layer 2007 may have a laminate structure as depicted in FIGS. 48A and 48B or a single-layer structure. The dielectric layer 2007 includes silicon oxide, silicon nitride, or the like as an example. As depicted in FIG. 47, the dielectric opening 2008 has the same shape as that of the first electrode 2003. However, the shape of the dielectric opening 2008 is not limited to the shape of the first electrode 2003, and may be partly formed on the first electrode 2003. The dielectric opening 2008 is filled with a conductive material not illustrated, and the conductive material is in contact with the first electrode 2003.

Furthermore, as depicted in FIGS. 48A and 48B, the surface emitting laser 2000 includes an optical opening 2009 inside the first electrode 2003. The surface emitting laser 2000 emits a light beam via the optical opening 2009. Furthermore, in the surface emitting laser 2000, the oxidized area 2006a of the oxidized constriction layer 2006 functions as a current and light confinement area in which current and light are confined. The non-oxidized area 2006b of the oxidized constriction layer 2006 is located below the optical opening 2009 and functions as a current and light passage area through which current and light pass.

Furthermore, the surface emitting laser 2000 includes a first multilayer reflector 2011 and a second multilayer reflector 2012. As an example, the multilayer reflector is a semiconductor multilayer reflector and is also referred to as a Distributed Bragg Reflector.

Furthermore, the surface emitting laser 2000 includes an active layer 2013. The active layer 2013 is disposed between a first multilayer reflector 2011 and a second multilayer reflector 2012 to confine injected carriers and to define the emission wavelength of the surface emitting laser 2000.

In the description of the present configuration example, as an example, the surface emitting laser 2000 is a front-side-emission surface emitting laser. However, the surface emitting laser 2000 can constitute a backside-emission surface emitting laser.

As depicted in FIGS. 47 and 48A, the substantial diameter of the surface emitting laser 2000 in the configuration example is a diameter d of a virtual circle defined by the trench 2005.

As an example, the surface emitting laser 2000 in the configuration example is manufactured by a procedure of steps 1 to 8 described below.
(Step 1) The first multilayer reflector 2011, the active layer 2013, a selected oxidation layer becoming the oxidized constriction layer 2006, and the second multilayer reflector 2012 are epitaxially grown on a front surface of the substrate 2001.
(Step 2) For example, liftoff is used to form a first electrode 2003 on the second multilayer reflector 2012.
(Step 3) For example, photolithography is used to form a trench 2005.
(Step 4) Side surfaces of the selected oxidation layer are exposed, and the selected oxidation layer is selectively oxidized from the side surfaces to form an oxidized constriction layer 2006.
(Step 5) Ion injection or the like is used to form a protection area 2002.
(Step 6) For example, vapor deposition, sputtering, or the like is used to deposit a dielectric layer 2007.
(Step 7) For example, photolithography is used to form a dielectric opening 2008 in the dielectric layer 2007 to expose a contact of the first electrode 2003.
(Step 8) The back surface of the substrate 2001 is polished and thinned, and then the second electrode 2004 is formed on the back surface of the substrate 2001.

The number, arrangement, thickness, arrangement order, symmetry, and the like of layers constituting the surface emitting laser 2000 are illustrative and can be changed as appropriate. That is, the surface emitting laser 2000 may include more or less layers, different layers, layers of different structures, or a different arrangement of layers compared with the layers depicted in FIGS. 47, 48A, and 48B.

The present technology can be applied to the surface emitting laser 2000 described above and modifications of the surface emitting laser 2000.

### Other Modifications

For example, current constriction performed in a case where the light emitting section is VCSEL is not limited to the effect of the oxidized constriction layer. For example, the current constriction may be performed by a circular ion injection area or may be performed by QWI, buried tunnel junction, or the like in which, for example, Ga vacancy diffusion is utilized to provide a bandgap energy difference between the inside and outside of an aperture to confine carriers.

For example, in a case where the light emitting section is a VCSEL, the oxidized constriction layer may be provided in the first reflector 201, in the first clad layer 202, and in the second clad layer 204, instead of or in addition to being provided in the second reflector 206.

For example, light constriction performed in a case where the light emitting section is a VCSEL is not limited to the effect of the oxidized constriction layer. For example, a step portion may be provided in a resonator to provide a difference in refractive index between the inside and outside of the aperture in such a manner that the refractive index is lower outside the aperture than inside the aperture.

For example, in a case where the light emitting section is a LED, a reflector may be provided on one side of the light emitting layer.

For example, the substrate 100 may be an Si substrate, a Ge substrate, a GaN substrate, an InP substrate, an SiC substrate, or the like. The element may be generated by joining of heterogeneous substrates in addition to epitaxial growth of the semi-conductor layer. The light emitting layer of the light emitting section (for example, VCSEL, LED, or the like) can include a material with any emission wavelength included in a wavelength band of from 200 to 2,000 nm.

In a case where the light emitting section is a VCSEL, each of the first and second reflectors 201 and 206 is not limited to a semiconductor but may include, for example, one or two types selected from a semiconductor, a dielectric, and metal.

The first reflector 201 may be provided opposite to the light emitting layer 203 side of the substrate 100. That is, the first element constitution section ES1 may include the first reflector 201 in addition to the substrate 100.

In a case where the elements are light emitting element (VCSEL, LED, or the like), the conductivity types (n type and p type) on one and the other sides of the light emitting layer may be changed to each other.

The optical element provided on the substrate 100 may be separated from the substrate 100. The optical element is not limited to a convex lens structure but may be, for example, a concave lens structure, a free-form surface lens structure, or a mirror structure (for example, a plane mirror, a convex mirror, a concave mirror, a free-form surface mirror, or the like). The lens structure or the mirror structure may include a meta surface.

Any parts of configurations of the optical apparatuses of the examples and modifications described above may be combined together to the extent that there is not in-consistency among the configurations.

In the examples and modifications described above, the material, conductivity type, thickness, width, numerical value, shape, size, and the like of each of the layers constituting the optical apparatus can be varied as appropriate to the extent that the optical apparatus functions as an optical apparatus.

### 17. Examples of Application to Electronic Equipment

The technology according to the present disclosure (present technology) can be applied to various products (electronic equipment). For example, the technology according to the present disclosure can be applied to an apparatus (for example, a distance measuring apparatus, a shape recognition apparatus, or the like) mounted in any type of mobile body such as an automobile, an electric vehicle, a hybrid electric vehicle, a motorcycle, a bicycle, a personal mobility device, an airplane, a drone, a ship, a robot, or the like, optical communication equipment, and low-consumption power equipment (for example, a smartphone, a smart watch, a tablet, a mouse, or the like).

The optical apparatus according to the present technology can be applied as, for example, equipment optically forming or displaying images (for example, a laser printer, a laser copier, a projector, a head mounted display, a head-up display, or the like) or a whole display, or a light receiving apparatus (solid image sensor) of a camera. The optical apparatus according to the present technology can also be applied to a light source apparatus for illumination.

### 18. Example of Applying Optical Apparatus to Distance Measuring Apparatus

Applied examples of the optical apparatuses according to the embodiments and modifications described above will be described below.

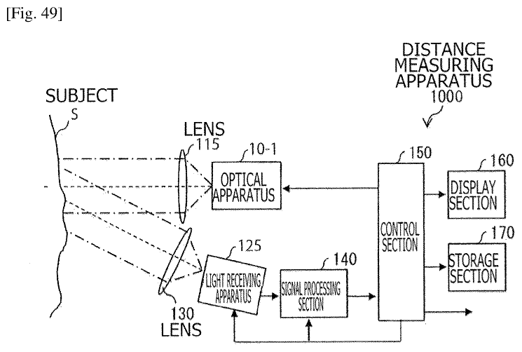

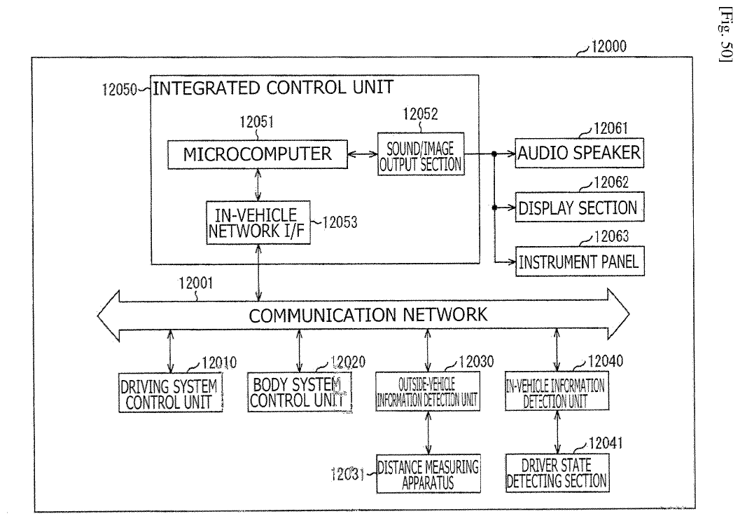

FIG. 49 represents an example of a general configuration of the distance measuring apparatus 1000 (distance measuring apparatus) including the optical apparatus 10-1. The distance measuring apparatus 1000 is configured to measure a distance to a subject S using a TOF (Time Of Flight) method. The distance measuring apparatus 1000 includes the optical apparatus 10-1 as a light source. The distance measuring apparatus 1000 includes, for example, the optical apparatus 10-1, a light receiving apparatus 125, lenses 115 and 130, a signal processing section 140, a control section 150, a display section 160, and a storage section 170.

The light receiving apparatus 125 detects light reflected from the subject S. The lens 115 is configured to parallelize light emitted from the optical apparatus 10-1 into parallel beams, and is a collimate lens. The lens 130 is configured to focus light reflected from the subject S and guide the light to the light receiving apparatus 125, and is a focusing lens. The light receiving apparatus 125 may include any one of the optical apparatuses 20-1 to 20-4 (optical apparatuses including solid image sensors) according to Examples 1 to 4 according to the second embodiment described above.

The signal processing section 140 is a circuit for generating a signal corresponding to a difference between a signal received from the light receiving apparatus 125 and a reference signal received from the control section 150. The control section 150 includes, for example, a Time to Digital Converter (TDC). The reference signal may be a signal received from the control section 150 or may be an output signal from a detection section directly detecting an output from the optical apparatus 10-1. The control section 150 is, for example, a processor that controls the optical apparatus 10-1, the light receiving apparatus 125, the signal processing section 140, the display section 160, and the storage section 170. The control section 150 is a circuit that measures the distance to the subject S on the basis of a signal generated by the signal processing section 140. The control section 150 generates a video signal for displaying information regarding the distance to the subject S, and outputs the video signal to the display section 160. The display section 160 displays the information regarding the distance to the subject S on the basis of the video signal received from the control section 150. The control section 150 stores, in the storage section 170, the information regarding the distance to the subject S.

In the present applied example, instead of the optical apparatus 10-1, any one of the optical apparatuses 10-2 to 10-11, 10-M1 to 10-M12 can also be applied to the light source of the distance measuring apparatus 1000.

### 19. Example of Application of Distance Measuring Apparatus to Mobile Body

FIG. 50 is a block diagram depicting a configuration example of a general configuration of a vehicle control system that is an example of a mobile body control system to which the technology according to the present disclosure may be applied.

The vehicle control system 12000 includes multiple electronic control units connected together via a communication network 12001. In an example illustrated in FIG. 50, the vehicle control system 12000 includes a driving system control unit 12010, a body system control unit 12020, an outside-vehicle information detection unit 12030, an in-vehicle information detection unit 12040, and an integrated control unit 12050. FIG. 50 also illustrates, as a functional configuration of the integrated control unit 12050, a microcomputer 12051, a sound/image output section 12052, and an in-vehicle network I/F (interface) 12053.

The driving system control unit 12010 controls the operation of apparatuses associated with a driving system of the vehicle according to various programs. For example, the driving system control unit 12010 functions as a control apparatus for a driving force generating apparatus such as an internal combustion engine, a driving motor, or the like which generates a driving force for the vehicle, a driving force transmitting mechanism for transmitting the driving force to wheels, a steering mechanism adjusting the steering angle of the wheels, a braking apparatus generating a braking force for the vehicle, and the like.

The body system control unit 12020 controls the operation of various apparatuses mounted in the vehicle body according to various programs. For example, the body system control unit 12020 functions as a control apparatus for a keyless entry system, a smart key system, a power window apparatus, or various lamps such as a head lamp, back lamp, a blinker, or a fog lamp. In this case, the body system control unit 12020 may receive the input of a radio wave transmitted from a portable equipment replacing a key and of signals for various switches. The body system control unit 12020 receives the inputs of the radio wave or signals to control a door lock apparatus, a power window apparatus, lamps, and the like of the vehicle.

The outside-vehicle information detection unit 12030 detects outside-vehicle information of the vehicle equipped with the vehicle control system 12000. For example, the outside-vehicle information detection unit 12030 connects to the distance measuring apparatus 12031. The distance measuring apparatus 12031 includes the distance measuring apparatus 1000 described above. The outside-vehicle information detection unit 12030 causes the distance measuring apparatus 12031 to measure a distance to an object (subject S) outside the vehicle, to acquire distance data obtained by the measurement. On the basis of the distance data acquired, the outside-vehicle information detection unit 12030 may execute object detection processing for a person, a car, an obstacle, a sign, and the like.

The in-vehicle information detection unit 12040 detects in-vehicle information. The in-vehicle information detection unit 12040 connects to, for example, a driver state detecting section 12041 that detects the state of the driver. The driver state detecting section 12041 includes a camera that captures an image of the driver, and on the basis of detection information received from the driver state detecting section 12041, the in-vehicle information detection unit 12040 may calculate the degree of fatigue or con-centration of the driver or determine whether the driver is snoozing.

On the basis of the in-vehicle and outside-vehicle information acquired by the outside-vehicle information detection unit 12030 or the in-vehicle information detection unit 12040, the microcomputer 12051 can calculate control target values for the driving force generating apparatus, the steering mechanism, or the braking apparatus and output control instructions to the driving system control unit 12010. For example, the microcomputer 12051 can perform cooperative control intended to implement functions of an ADAS (Advanced Driver Assistance System) including collision avoidance or shock cushioning for the vehicle, adaptive control based on inter-vehicle distance, constant speed traveling, collision warning for the vehicle, lane departure warning for the vehicle, or the like.

Additionally, by controlling the driving force generating apparatus, the steering mechanism, the control apparatus, or the like on the basis of information regarding the surroundings of the vehicle acquired by the outside-vehicle information detection unit 12030 or the in-vehicle information detection unit 12040, the microcomputer 12051 can perform cooperative control intended for self-driving in which the vehicle travels autonomously without relying on the operation of the driver, and the like.

Additionally, the microcomputer 12051 can output control instructions to the body system control unit 12020 on the basis of the outside-vehicle information acquired by the outside-vehicle information detection unit 12030. For example, the microcomputer 12051 controls the head lamp according to the position of a preceding vehicle or an oncoming vehicle detected by the outside-vehicle information detection unit 12030, and can perform cooperative control intended for prevention of glare such as switching from a high beam to a low beam.

The sound/image output section 12052 transmits an output signal for at least one of sound and image to an output apparatus that can notify visual or aural information to an occupant of the vehicle or the exterior. In the example in FIG. 50, the output apparatus is illustrated as an audio speaker 12061, a display section 12062, and an instrument panel 12063. The display section 12062 may include at least one of, for example, an onboard display and a head-up display.

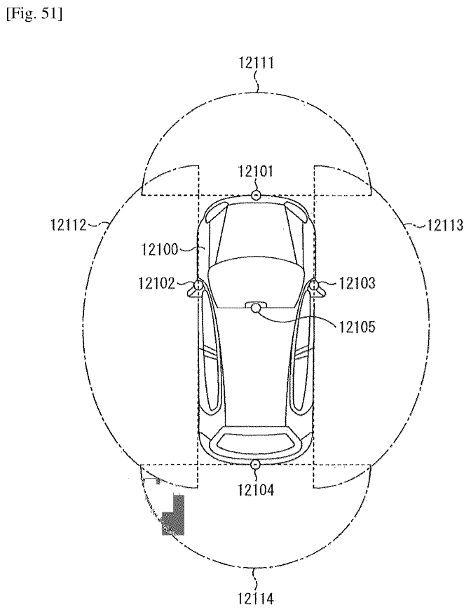

FIG. 51 is a diagram depicting an example of an installation position of the distance measuring apparatus 12031.

In FIG. 51, the vehicle 12100 includes, as the distance measuring apparatus 12031, distance measuring apparatuses 12101, 12102, 12103, 12104, and 12105.

The distance measuring apparatuses 12101, 12102, 12103, 12104, and 12105 are provided at, for example, a front nose, side mirrors, a rear bumper, and a back door of the vehicle 12100, an upper portion of a windshield in the interior, and the like. For the distance measuring apparatus 12101 provided at the front nose and the distance measuring apparatus 12105 provided at the upper portion of the windshield in the interior, data regarding the front of the vehicle 12100 is mainly acquired. The distance measuring apparatuses 12102 and 12103 provided at the side mirrors mainly acquire data regarding the sides of the vehicle 12100. The distance measuring apparatus 12104 provided at the rear bumper or the back door mainly acquire data regarding the back of the vehicle 12100. The data regarding the front acquired by the distance measuring apparatuses 12101 and 12105 is mainly used to detect a passenger, an obstacle, a traffic light, a traffic sign, and the like.

Note that FIG. 51 illustrates examples of detection ranges of the distance measuring apparatuses 12101 to 12104. A detection range 12111 depicts the detection range of the distance measuring apparatus 12101 provided at the front nose, detection ranges 12112 and 12113 depict the detection ranges of the distance measuring apparatuses 12102 and 12103 provided at the respective side mirrors, and a detection range 12114 depicts the detection range of the distance measuring apparatus 12104 provided at the rear bumper or the back door.

For example, by determining a distance to each of the three-dimensional objects within the detection ranges 12111 to 12114 and a temporal change in the distance (speed relative to the vehicle 12100) on the basis of distance data obtained from the distance measuring apparatuses 12101 to 12104, the microcomputer 12051 can extract, as a preceding vehicle, a three-dimensional object closest to the vehicle 12100 on a traveling path of the vehicle 12100 and traveling at a predetermined speed (for example, 0 km/h or more) in substantially the same direction as the vehicle 12100. Furthermore, the microcomputer 12051 can set an inter-vehicle distance to be provided on the near side of the preceding vehicle in advance and perform automatic brake control (including follow-up stop control), automatic acceleration control (including follow-up start control), and the like. As described above, cooperative control can be performed that is intended for self-driving in which the vehicle travels autonomously without relying on the operation of the driver, and the like.

For example, on the basis of the distance data obtained from the distance measuring apparatuses 12101 to 12105, the microcomputer 12051 can classify three-dimensional object data related to three-dimensional objects into two-wheeled vehicles, standard-sized vehicles, large-sized vehicles, passengers, electric poles and the like, and other three-dimensional objects for extraction and use the extracted three-dimensional object data to automatically avoid obstacles. For example, among the obstacles around the vehicle 12100, the microcomputer 12051 discriminate between obstacles visible by the driver of the vehicle 12100 and obstacles difficult to view. Then, the microcomputer can determine a collision risk indicating the degree of risk of collision with each of the obstacle, and when the collision risk is equal to or higher than a set value, indicating the possibility of a collision, output a warning to the driver via the audio speaker 12061 or the display section 12062, perform forced deceleration or avoiding steering via the driving system control unit 12010, or provide driving assistance for collision avoidance.

An example of the mobile body control system has been described to which the technology according to the present disclosure may be applied. The technology according to the present disclosure may be applied to the distance measuring apparatus among the configurations described above.

Further, the present technology can also have the following configurations.
(1)
A light emitting device comprising:
a substrate including a plurality of light emitting sections; and
a film disposed on the substrate,
wherein the substrate includes a groove surface at an end of a surface of the substrate.
(2)
The light emitting device of (1), wherein the film is a thin film.
(3)
The light emitting device of (1) or (2), wherein the film is an anti-reflection film.
(4)
The light emitting device of any one of (1) to (3), wherein the film is disposed on the groove surface.
(5)
The light emitting device of any one of (1) to (4), wherein the film is an electrode.
(6)
The light emitting device of any one of (1) to (5), wherein the film includes wiring.
(7)
The light emitting device of any one of (1) to (6), wherein the film is an Au thin film.
(8)
The light emitting device of any one of (1) to (4), wherein the film comprises an anode electrode and an insulating film.
(9)
The light emitting device of any one of (1) to (8), wherein each light emitting section is a vertical cavity surface emitting laser (VCSEL).
(10)
The light emitting device of any one of (1) to (9), wherein the light emitting device is a back side emitting type.
(11)
The light emitting device of any one of (1) to (10), wherein the plurality of light emitting sections are arranged in two dimensionally in a staggered arrangement.
(12)
The light emitting device of any one of (1) to (11), wherein the substrate includes a plurality of optical elements, each corresponding to a respective light emitting section.
(13) The light emitting device of (12), wherein the optical elements are convex lenses.
(14)
The light emitting device of any one of (1) to (14), wherein the groove surface is a first surface of a groove in the substrate, the groove having the first surface and a second surface which are symmetrically shaped.
(15)
The light emitting device of (14), wherein the groove is a V-shaped groove, which upon separation, provides the groove surface as a chamfered portion at the end of the surface of the substrate.
(16)
The light emitting device of (15), wherein the second surface of the groove is removed from the light emitting device after separation of the substrate.
(17)
The light emitting device of (14), wherein the groove surface is a curved surface.
(18)
The light emitting device of any one of (1) to (16), wherein with respect to a thickness direction of the substrate, the groove surface has an inclination angle of 60° or less.
(19)
A method of manufacturing light emitting devices, comprising:
forming a plurality of light emitting sections on a first surface of a substrate;
forming a plurality of grooves on a second surface of the substrate;
forming a film on the second surface;
sticking a tape to the second surface;
releasing a plurality of light emitting devices from the tape.
(20)
The method of any one of (19), wherein the light emitting devices are optical chips.
(21)
The method of any one of (20), wherein each of the optical chips include a plurality of back side emitting vertical cavity surface emitting lasers.
(22)
The method of any one of (19) to (21), further comprising forming optical elements on the second surface.
(23)
The method of any one of (19) to (22), wherein the grooves are formed by etching.
(24)
The method of any one of (19) to (23), wherein the tape includes at least one of a dicing tape or a protection tape.
(25)
An optical apparatus including:
an element that includes
a first element constitution section including a substrate, and
a second element constitution section provided on one surface of the substrate, in which
the substrate includes a chamfered portion at ends of another surface side opposite to the one surface side and/or at ends of the one surface side.
(26)
The optical apparatus according to (25), in which,
in a case where the substrate includes the chamfered portion at the ends of the other surface side, the first element constitution section is covered by a thin film from the other surface side, and
in a case where the substrate includes the chamfered portion at the ends of the one surface side, the second element constitution section is covered by a thin film from the one surface side.
(27)
The optical apparatus according to (25) or (26), in which,
in a case where the substrate includes the chamfered portion at the ends of the other surface side, the other surface and the chamfered portion are covered by the thin film, and,
in a case where the substrate includes the chamfered portion at the ends of the one surface side, the one surface and the chamfered portion are covered by the thin film.
(28)
The optical apparatus according to any one of (25) to (27), in which
the substrate includes the chamfered portion at the ends of the other surface side,
the first element constitution section includes an optical element provided on the other surface, and
at least the optical element and the chamfered portion are covered by the thin film.
(29)
The optical apparatus according to any one of (25) to (28), in which
the chamfered portion has an inclination angle of 60° or less relative to a thickness direction of the substrate.
(30)
The optical apparatus according to any one of (25) to (29), in which,
for the chamfered portion, a ratio of a length related to a thickness direction of the substrate to a length related to an in-plane direction of the substrate is 2 or more.
(31)
The optical apparatus according to any one of (25) to (30), in which
a length of the chamfered portion related to a thickness direction of the substrate is one-third or less of a thickness of the substrate.
(32)
The optical apparatus according to any one of (26) to (31), in which
the thin film includes an anti-reflection film.
(33)
The optical apparatus according to any one of (25) to (32), in which
the second element constitution section includes a light emitting layer.
(34)
The optical apparatus according to (33), in which
the second element constitution section includes a first reflector and a second reflector between which the light emitting layer is sandwiched, or the first element constitution section includes the first reflector, and the second element constitution section includes the second reflector.
(35)
The optical apparatus according to (33) or (34), in which
the second element constitution section includes a mesa including the light emitting layer.
(36)
The optical apparatus according to any one of (25) to (35), in which
the substrate includes a semiconductor substrate.
(37)
The optical apparatus according to any one of (25) to (36), in which
the optical apparatus further includes another substrate joined to the element.
(38)
A method for manufacturing an optical apparatus, the method including:
a step of forming a tapered groove in another surface of a wafer at a scribe position of the wafer, the wafer being shared by multiple first element constitution sections and provided, on one surface of the wafer, with multiple second element constitution sections corresponding to the multiple first element constitution sections;
a step of forming a crack at the scribe position of the wafer from the one surface side; and
a step of dividing the wafer at the scribe position to obtain multiple optical chips including the first and second element constitution sections.
(39)
The method for manufacturing an optical apparatus according to (38), in which,
in the step of forming the crack, the crack is formed by irradiating the scribe position with laser light from the one surface side.
(40)
The method for manufacturing an optical apparatus according to (38) or (39), in which,
in the step of forming the tapered groove, the wafer is etched from the other surface side to form the tapered groove and an optical element of the other surface.
(41)
The method for manufacturing an optical apparatus according to any one of (38) to (40), including:
a step of forming a thin film on the other surface provided with the tapered groove before the step of forming the crack;
a step of sticking a dicing tape to surfaces of the multiple optical chips on the thin film side after the step of forming the thin film and before the step of forming the crack; and
a step of releasing the multiple optical chips from the dicing tape after the step of obtaining.
(42)
The method for manufacturing an optical apparatus according to any one of (38) to (41), including:
a step of joining the second element constitution sections of the multiple optical chips to another wafer via a bump after the step of obtaining;
a step of sticking a protection tape to surfaces of the multiple optical chips opposite to the other wafer side;
a step of grinding and thinning the other wafer; and
a step of releasing the protection tape from the multiple optical chips.
(43)
The method for manufacturing an optical apparatus according to (42), including:
a step of dicing the other wafer to obtain multiple optical apparatuses each including a respective one of the multiple optical chips after the step of releasing the protection tape.
(44)
The method for manufacturing an optical apparatus according to (42), including:
a step of filling a periphery of a junction between the second element constitution sections of the multiple optical chips and the other wafer with underfill after the step of joining.
(45)
A method for manufacturing an optical apparatus, the method including:
a step of forming a tapered groove in one surface of a wafer at a scribe position of the wafer, the wafer being shared by multiple first element constitution sections and provided, on one surface of the wafer, with multiple second element constitution sections corresponding to the multiple first element constitution sections;
a step of forming a crack at the scribe position of the wafer from the other surface side; and
a step of dividing the wafer at the scribe position to obtain optical chips each including the first and second element constitution sections.
(46)
The method for manufacturing an optical apparatus according to (45), in which,
in the step of forming the crack, the crack is formed by irradiating the scribe position with laser light from the other surface side.
(47)
The method for manufacturing an optical apparatus according to (45) or (46), the method including:
a step of forming a thin film on the one surface provided with the tapered groove before the step of forming the crack;
a step of sticking a dicing tape to surfaces of the multiple optical chips on the thin film side after the step of forming the thin film and before the step of forming the crack; and
a step of releasing the multiple optical chips from the dicing tape after the step of obtaining.
(48)
The method for manufacturing an optical apparatus according to any one of (45) to (47), the method including:
a step of joining the multiple optical chips to another wafer after the step of obtaining;
a step of sticking a protection tape to surfaces of the multiple optical chips opposite to the other wafer side, grinding and thinning the other wafer; and
a step of releasing the protection tape from the multiple optical chips.
(49)
The method for manufacturing an optical apparatus according to (48), the method including:
a step of dicing the other wafer to obtain multiple optical apparatuses each including a respective one of multiple optical chips.
(50)
The method for manufacturing an optical apparatus according to (48) or (49), the method including:
a step of filling a periphery of a junction between the second element constitution sections of the multiple optical chips and the other wafer with underfill after the step of joining.
(B1)
An optical apparatus including:
an element that includes
a first element constitution section including a substrate, and
a second element constitution section provided on one surface of the substrate, in which
the substrate includes a chamfered portion at ends of another surface side opposite to the one surface side and/or at ends of the one surface side.
(B2)
The optical apparatus according to (B1), in which,
in a case where the substrate includes the chamfered portion at the ends of the other surface side, the first element constitution section is covered by a thin film from the other surface side, and
in a case where the substrate includes the chamfered portion at the ends of the one surface side, the second element constitution section is covered by a thin film from the one surface side.
(B3)
The optical apparatus according to (B1) or (B2), in which,
in a case where the substrate includes the chamfered portion at the ends of the other surface side, the other surface and the chamfered portion are covered by the thin film, and,
in a case where the substrate includes the chamfered portion at the ends of the one surface side, the one surface and the chamfered portion are covered by the thin film.
(B4)
The optical apparatus according to any one of (B1) to (B3), in which
the substrate includes the chamfered portion at the ends of the other surface side, the first element constitution section includes an optical element provided on the other surface, and
at least the optical element and the chamfered portion are covered by the thin film.
(B5)
The optical apparatus according to any one of (B1) to (B4), in which
the chamfered portion has an inclination angle of 60° or less relative to a thickness direction of the substrate.
(B6)
The optical apparatus according to any one of (B1) to (B5), in which,
for the chamfered portion, a ratio of a length related to a thickness direction of the substrate to a length related to an in-plane direction of the substrate is 2 or more.
(B7)
The optical apparatus according to any one of (B1) to (B6), in which
a length of the chamfered portion related to a thickness direction of the substrate is one-third or less of a thickness of the substrate.
(B8)
The optical apparatus according to any one of (B2) to (B7), in which
the thin film includes an anti-reflection film.
(B9)
The optical apparatus according to any one of (B1) to (B8), in which
the second element constitution section includes a light emitting layer.
(B10)
The optical apparatus according to (B9), in which
the second element constitution section includes a first reflector and a second reflector between which the light emitting layer is sandwiched, or the first element constitution section includes the first reflector, and the second element constitution section includes the second reflector.
(B11)
The optical apparatus according to (B9) or (B10), in which
the second element constitution section includes a mesa including the light emitting layer.
(B12)
The optical apparatus according to any one of (B1) to (B11), in which
the substrate includes a semiconductor substrate.
(B13)
The optical apparatus according to any one of (B1) to (B12), in which
the optical apparatus further includes another substrate joined to the element.
(B14)
A method for manufacturing an optical apparatus, the method including:
a step of forming a tapered groove in another surface of a wafer at a scribe position of the wafer, the wafer being shared by multiple first element constitution sections and provided, on one surface of the wafer, with multiple second element constitution sections corresponding to the multiple first element constitution sections;
a step of forming a crack at the scribe position of the wafer from the one surface side; and
a step of dividing the wafer at the scribe position to obtain multiple optical chips including the first and second element constitution sections.
(B15)
The method for manufacturing an optical apparatus according to (B14), in which,
in the step of forming the crack, the crack is formed by irradiating the scribe position with laser light from the one surface side.
(B16)
The method for manufacturing an optical apparatus according to (B14) or (B15), in which,
in the step of forming the tapered groove, the wafer is etched from the other surface side to form the tapered groove and an optical element of the other surface.
(B17)
The method for manufacturing an optical apparatus according to any one of (B14) to (B16), including:
a step of forming a thin film on the other surface provided with the tapered groove before the step of forming the crack;
a step of sticking a dicing tape to surfaces of the multiple optical chips on the thin film side after the step of forming the thin film and before the step of forming the crack; and
a step of releasing the multiple optical chips from the dicing tape after the step of obtaining.
(B18)
The method for manufacturing an optical apparatus according to any one of (B14) to (B17), including:
a step of joining the second element constitution sections of the multiple optical chips to another wafer via a bump after the step of obtaining;
a step of sticking a protection tape to surfaces of the multiple optical chips opposite to the other wafer side;
a step of grinding and thinning the other wafer; and
a step of releasing the protection tape from the multiple optical chips.
(B19)
The method for manufacturing an optical apparatus according to (B18), including:
a step of dicing the other wafer to obtain multiple optical apparatuses each including a respective one of the multiple optical chips after the step of releasing the protection tape.
(B20)
The method for manufacturing an optical apparatus according to (B18), including:
a step of filling a periphery of a junction between the second element constitution sections of the multiple optical chips and the other wafer with underfill after the step of joining.
(B21)
A method for manufacturing an optical apparatus, the method including:
a step of forming a tapered groove in one surface of a wafer at a scribe position of the wafer, the wafer being shared by multiple first element constitution sections and provided, on one surface of the wafer, with multiple second element constitution sections corresponding to the multiple first element constitution sections;
a step of forming a crack at the scribe position of the wafer from the other surface side; and
a step of dividing the wafer at the scribe position to obtain optical chips each including the first and second element constitution sections.
(B22)
The method for manufacturing an optical apparatus according to (B21), in which,
in the step of forming the crack, the crack is formed by irradiating the scribe position with laser light from the other surface side.
(B23)
The method for manufacturing an optical apparatus according to (B21) or (B22), the method including:
a step of forming a thin film on the one surface provided with the tapered groove before the step of forming the crack;
a step of sticking a dicing tape to surfaces of the multiple optical chips on the thin film side after the step of forming the thin film and before the step of forming the crack; and
a step of releasing the multiple optical chips from the dicing tape after the step of obtaining.
(B24)
The method for manufacturing an optical apparatus according to any one of (B21) to (B23), the method including:
a step of joining the multiple optical chips to another wafer after the step of obtaining;
a step of sticking a protection tape to surfaces of the multiple optical chips opposite to the other wafer side, grinding and thinning the other wafer; and
a step of releasing the protection tape from the multiple optical chips.
(B25)
The method for manufacturing an optical apparatus according to (B24), the method including:
a step of dicing the other wafer to obtain multiple optical apparatuses each including a respective one of multiple optical chips.
(B26)
The method for manufacturing an optical apparatus according to (B24) or (B25), the method including:
a step of filling a periphery of a junction between the second element constitution sections of the multiple optical chips and the other wafer with underfill after the step of joining.

### REFERENCE SIGNS LIST

10-1 to 10-11, 20-1 to 20-4, 10-M1 to 10-M12: Optical apparatus
100: Substrate
100a: Optical element
100b: Chamfered portion
100W: Wafer
101: Thin film
201: First reflector
203: Light emitting layer
206: Second reflector
300: Another substrate
300W: Another wafer
400: Bump
500: Underfill
ES1: First element constitution section
ES2: Second element constitution section
T: Thickness of substrate
Φ: Inclination angle
Dv: Length of chamfered portion related to thickness direction of substrate
Dh: Length of chamfered portion related to in-plane direction of substrate
VT: Tapered groove
C: Crack
DT: Dicing tape
OC: Optical chip
PT: Protection tape

1. A light emitting device comprising:
a substrate including a plurality of light emitting sections; and
a film disposed on the substrate,
wherein the substrate includes a groove surface at an end of a surface of the substrate.

2. The light emitting device of claim 1, wherein the film is a thin film.

3. The light emitting device of claim 1, wherein the film is an anti-reflection film.

4. The light emitting device of claim 1, wherein the film is disposed on the groove surface.

5. The light emitting device of claim 1, wherein the film is an electrode.

6. The light emitting device of claim 1, wherein the film includes wiring.

7. The light emitting device of claim 1, wherein the film is an Au thin film.

8. The light emitting device of claim 1, wherein the film comprises an anode electrode and an insulating film.

9. The light emitting device of claim 1, wherein each light emitting section is a vertical cavity surface emitting laser (VCSEL).

10. The light emitting device of claim 1, wherein the light emitting device is a back side emitting type.

11. The light emitting device of claim 1, wherein the plurality of light emitting sections are arranged in two dimensionally in a staggered arrangement.

12. The light emitting device of claim 1, wherein the substrate includes a plurality of optical elements, each corresponding to a respective light emitting section.

13. The light emitting device of claim 12, wherein the optical elements are convex lenses.

14. The light emitting device of claim 1, wherein the groove surface is a first surface of a groove in the substrate, the groove having the first surface and a second surface which are symmetrically shaped.

15. The light emitting device of claim 14, wherein the groove is a V-shaped groove, which upon separation, provides the groove surface as a chamfered portion at the end of the surface of the substrate.

16. The light emitting device of claim 15, wherein the second surface of the groove is removed from the light emitting device after separation of the substrate.

17. The light emitting device of claim 14, wherein the groove surface is a curved surface.

18. The light emitting device of claim 1, wherein with respect to a thickness direction of the substrate, the groove surface has an inclination angle of 60° or less.

19. A method of manufacturing light emitting devices, comprising:
forming a plurality of light emitting sections on a first surface of a substrate;
forming a plurality of grooves on a second surface of the substrate;
forming a film on the second surface;
sticking a tape to the second surface;
releasing a plurality of light emitting devices from the tape.

20. The method of claim 19, wherein the light emitting devices are optical chips.

21. The method of claim 20, wherein each of the optical chips include a plurality of back side emitting vertical cavity surface emitting lasers.

22. The method of claim 19, further comprising forming optical elements on the second surface.

23. The method of claim 19, wherein the grooves are formed by etching.

24. The method of claim 19, wherein the tape includes at least one of a dicing tape or a protection tape.
